(19) United States
(12) Patent Application Publication
(10) Pub. No.: US 2019/0264035 A1
(43) Pub. Date: Aug. 29, 2019

(54) SEMICONDUCTOR SUBSTRATE TREATMENT AGENT AND SUBSTRATE-TREATING METHOD

(71) Applicant: JSR CORPORATION, Tokyo (JP)

(72) Inventors: Shun AOKI, Tokyo (JP); Kang-go CHUNG, Tokyo (JP); Yuushi MATSUMURA, Tokyo (JP); Tomohiro MATSUKI, Tokyo (JP); Yoshio TAKIMOTO, Tokyo (JP)

(73) Assignee: JSR CORPORATION, Tokyo (JP)

(21) Appl. No.: 16/388,267

(22) Filed: Apr. 18, 2019

Related U.S. Application Data
(63) Continuation of application No. PCT/JP2017/037767, filed on Oct. 18, 2017.

(30) Foreign Application Priority Data
Oct. 21, 2016 (JP) 2016-207389

(51) Int. Cl. C09D 5/00; C09D 161/06; C09D 161/18; C09D 161/34; C09D 125/06; C09D 161/12; C09D 125/18; H01L 21/02; H01L 21/311

(52) U.S. Cl. CPC C09D 5/008; C09D 161/06; C09D 161/18; C09D 161/34; H01L 21/31138; C09D 161/12; C09D 125/18; H01L 21/02118; H01L 21/02282; C09D 125/06

(57) ABSTRACT

A substrate-treating method includes applying a treatment agent directly or indirectly on one face of a substrate to form a substrate pattern collapse-inhibitory film. The substrate includes a pattern on the one face. The substrate pattern collapse-inhibitory film is removed by dry etching after forming the substrate pattern collapse-inhibitory film. The treatment agent includes a compound including an aromatic ring, and a hetero atom-containing group that bonds to the aromatic ring; and a solvent.

### CROSS-REFERENCE TO RELATED APPLICATIONS

The present application is a continuation application of International Application No. PCT/JP2017/037767, filed Oct. 18, 2017, which claims priority to Japanese Patent Application No. 2016-207389, filed Oct. 21, 2016. The contents of these applications are incorporated herein by reference in their entirety.

### BACKGROUND OF THE INVENTION

### Field of Invention

The present invention relates to a semiconductor substrate treatment agent and a substrate-treating method.

### Description of the Related Art

In manufacturing steps of semiconductor apparatuses, micro electro mechanical systems (MEMS) and the like, a substrate (i.e., treatment object) is treated with a liquid. For example, a substrate, a laminated film, a resist film or the like is subjected to a patterning processing by a liquid treatment, etc., whereby a fine structure is formed on the substrate. Moreover, impurities, residues and the like remaining on the substrate are removed by washing with a liquid. Furthermore, these steps are carried out in combination. Then, in removing the liquid after the liquid treatment, the fine structure formed on the substrate may be collapsed due to the surface tension of the liquid.

Meanwhile, microfabrication of a pattern formed on the surface of a substrate (hereinafter, may be also referred to as “substrate pattern”) has been further in progress along with further miniaturization, enhanced integration or increased speed of semiconductor devices for use in networks and/or digital household appliances. Due to an increase in the aspect ratio with advanced microfabrication of substrate patterns, a drawback may arise that a substrate pattern is likely to collapse when the gas-liquid interface passes through the pattern while a wafer is dried after being washed or rinsed. Since no practical solution to the drawback is attained, it is necessary to, for example, design a pattern that is resistant to collapse, for further miniaturization, enhanced integration or increased speed of semiconductor devices and/or micromachines, resulting in significant impairment of the freedom in the design of patterns.

Japanese Unexamined Patent Application, Publication No. 2008-198958 discloses a procedure of inhibiting the substrate pattern collapse, i.e., a technique of changing a washing liquid from water to 2-propanol before the gas-liquid interface passes through the pattern. However, the technique is reportedly subject to, for example, the limitation that an adaptable aspect ratio of the pattern is no greater than 5.

Additionally, Japanese Patent No. 4403202 discloses a cleaning procedure in which modification of a wafer surface having an uneven pattern formed from a film containing silicon by oxidization or the like is conducted and then a water-repellent protecting film is formed on the surface by using a water-soluble surfactant or a silane coupling agent, thereby reducing the capillary force to prevent pattern collapse.

Furthermore Japanese Unexamined Patent Application, Publication No. 2010-129932 and PCT International Publication No. 2010/47196 Pamphlet disclose a technique for preventing substrate pattern collapse by conducting a hydrophobilization treatment through the use of a treatment liquid containing: a silylation agent such as N,N-dimethylaminotrimethylsilane; and a solvent.

### SUMMARY OF THE INVENTION

According to an aspect of the present invention, a substrate-treating method includes applying a treatment agent directly or indirectly on one face of a substrate to form a substrate pattern collapse-inhibitory film. The substrate includes a pattern on the one face. The substrate pattern collapse-inhibitory film is removed by dry etching after forming the substrate pattern collapse-inhibitory film. The treatment agent includes a compound including an aromatic ring, and a hetero atom-containing group that bonds to the aromatic ring; and a solvent.

According to another aspect of the present invention, a semiconductor substrate treatment agent includes a compound including an aromatic ring, and a hetero atom-containing group that bonds to the aromatic ring; and a solvent, wherein the semiconductor substrate treatment agent is suitable for forming a film to prevent a collapse of a pattern of a substrate.

### DESCRIPTION OF THE EMBODIMENTS

Hereinafter, embodiments of the present invention will be described, but the present invention is not in any way limited to the embodiments. In other words, the embodiments which may be altered and/or modified as appropriate on the basis of the common knowledge of one of ordinary skill in the art within a range not departing from principles of the present invention are to be construed to fall within the scope of the present invention.

According to one embodiment of the invention, a semiconductor substrate treatment agent is capable of inhibiting collapse of a pattern formed on the surface of a substrate, and contains a compound having an aromatic ring, and a hetero atom-containing group that bonds to the aromatic ring (hereinafter, may be also referred to as “(A) compound” or “compound (A)”), and a solvent (hereinafter, may be also referred to as “(B) solvent” or “solvent (B)”), wherein the semiconductor substrate treatment agent is suitable for forming a film to prevent a collapse of a pattern of a substrate.

According to another embodiment of the invention, a substrate-treating method includes: applying the treatment agent of the one embodiment of the invention directly or indirectly on one face of a substrate to form a substrate pattern collapse-inhibitory film, the substrate having a pattern on the one face (i.e., substrate provided with a pattern on one face thereof).

The term “pattern formed on the surface of a substrate” or “substrate pattern” as referred to herein means a pattern other than a resist pattern formed on the substrate. The term “hetero atom” as referred to herein means an atom other than a carbon atom and a hydrogen atom. The “hetero atom-containing group” as referred to herein may be a group formed from only the hetero atom, or may be a group formed by combining the hetero atom with at least one of the carbon atom and the hydrogen atom.

The semiconductor substrate treatment agent and the substrate-treating method according to the embodiments of the present invention achieve a substrate-pattern collapse-inhibitory property each being superior. In addition, for example, when a residue of the substrate pattern collapse-inhibitory film is generated in the removing of the substrate pattern collapse-inhibitory film (removing step), the residue may result in a defect of the substrate pattern; however, the treatment agent and the substrate-treating method of the embodiments of the present invention are superior in a substrate-pattern defect-inhibitory property in the treatment. Therefore, these can be suitably used in manufacture of semiconductor devices or micro electro mechanical systems in which further progress of miniaturization is expected in the future.

### Semiconductor Substrate Treatment Agent

The semiconductor substrate treatment agent of one embodiment of the present invention contains: the compound (A) having an aromatic ring, and a hetero atom-containing group that bonds to the aromatic ring; and the solvent (B). The semiconductor substrate treatment agent (hereinafter, may be merely referred to as “treatment agent”) is suitably used in a substrate-treating method which includes applying a treatment agent directly or indirectly on one face of a substrate to form a substrate pattern collapse-inhibitory film, the substrate having a pattern on the one face.

The treatment agent may be used for filling the gaps of the substrate pattern. Specifically, after washing, etc., of the substrate having a pattern on one face, the treatment agent is applied directly or indirectly on the one face of the substrate. As a result, the liquid on the substrate such as a washing liquid and rinse agent is replaced with the treatment agent, whereby a coating film (substrate pattern collapse-inhibitory film) is formed that fills the gaps of the substrate pattern. Since the liquid can be removed without employing the operation of drying the liquid in the method, pattern collapse resulting from the gas-liquid interface running along the lateral faces in the substrate pattern is inhibited. The substrate pattern collapse-inhibitory film can be removed from the substrate as needed, by dry etching or the like.

Due to containing the compound (A) and the solvent (B), the treatment agent is superior in substrate-pattern collapse-inhibitory property and substrate-pattern defect-inhibitory property. Although not necessarily clarified and without wishing to be bound by any theory, the reason for achieving the aforementioned effect due to the constitution of the treatment agent described above is inferred as follows, for example. Specifically, the substrate having a pattern to be treated with the treatment agent tends to have comparatively high hydrophilicity on the surface owing to including, in general, a silicon atom, a metal element, etc. In contrast, since the treatment agent of the embodiment of the present invention contains the compound (A) having appropriate hydrophilicity, it is considered that affinity to the surface of the substrate can be improved. As a result, it is believed that the treatment agent enables the coating characteristics, as well as a performance of reliably filling the gaps of the substrate pattern with the substrate pattern collapse-inhibitory film to be formed (filling property) to be improved, thereby being capable of exerting a superior substrate-pattern collapse-inhibitory property and substrate-pattern defect-inhibitory property. In addition, due to the aromatic ring included in the compound (A), the treatment agent is believed to enable the defect-inhibitory-property to be more improved.

(A) Compound

The compound (A) has an aromatic ring, and a hetero atom-containing group that bonds to the aromatic ring. The compound (A) may have one type or two or more types of each of the aromatic ring and the hetero atom-containing group. It is to be noted that the compound (A) may further have an aromatic ring to which a hetero atom-containing group is not bonded. Either alone of one type, or in combination of two or more types of the compound (A) may be used.

The aromatic ring is not particularly limited, and may be a monocyclic ring, a fused ring, a hydrocarbon aromatic ring or a heteroaromatic ring, and is exemplified by a benzene ring, a naphthalene ring, an anthracene ring, a pyrene ring, an acenaphthylene ring, a fluorene ring, a phenanthrene ring, an indene ring, a triazine ring, and the like.

The hetero atom-containing group may be a substituent that bonds to only one aromatic ring, or a lining group that bonds to a plurality of aromatic rings.

With respect to the valency of the hetero atom-containing group, for example, a monovalent to decavalent hetero atom-containing group is exemplified, a monovalent to pentavalent hetero atom-containing group is preferred, and a monovalent or divalent hetero atom-containing group is more preferred.

The number of carbon atoms in the hetero atom-containing group is, for example, no less than 0 and no greater than 20, more preferably no less than 0 and no greater than 10, and still more preferably no less than 0 and no greater than 3.

Examples of the hetero atom contained in the hetero atom-containing group include: halogen atoms such as a chlorine atom, a bromine atom and an iodine atom; an oxygen atom; a nitrogen atom; a sulfur atom, a phosphorus atom, and the like. The hetero atom-containing group may have one type of the hetero atom, or two or more types of the hetero atom.

Examples of the hetero atom-containing group include:

monovalent hetero atom-containing groups (α) such as a hydroxy group, a carboxy group, a cyano group, an amino group, a sulfo group, a halogen atom, a sulfanyl group and a nitro group;

divalent hetero atom-containing groups (β) such as a carbonyl group, an oxy group, a sulfonyl group, —CS—, —NR′— and —S—;

groups (γ) that include the divalent hetero atom-containing group (β) between two adjacent carbon atoms or at the end of the atomic bonding side of any of chain hydrocarbon groups and alicyclic hydrocarbon groups, such as a methanediyloxy group, an ethanediyloxy group and a cyclohexanediyloxy group;

groups (ω) obtained by substituting with the monovalent hetero atom-containing group (α), a part or all of hydrogen atoms included in any of chain hydrocarbon groups such as a hydroxymethyl group, a hydroxyethyl group, a cyanomethyl group and a cyanoethyl group, an alicyclic hydrocarbon group, and the groups (γ);

groups (δ) that include the divalent hetero atom-containing group (β) between two adjacent carbon atoms or at the end of the atomic bonding side of any of aromatic hydrocarbon groups such as a phenoxy group, a benzyloxy group, an o-, m- or p-vinylbenzyloxy group, and an o-, m- or p-methoxyphenyl group;

groups (ε) obtained by substituting with the monovalent hetero atom-containing group (α), a part or all of hydrogen atoms included in any of the groups (δ) and aromatic hydrocarbon groups such as a hydroxyphenyl group, a hydroxynaphthyl group and a (hydroxyphenyl)methyl group; and the like. R′ represents a monovalent hydrocarbon group having 1 to 10 carbon atoms.

The hetero atom-containing group is preferably a group containing an oxygen atom, a nitrogen atom, a sulfur atom, a halogen atom or a combination thereof, more preferably a group containing a hydroxy group, a carboxy group, a cyano group, an amino group, a sulfo group, a halogen atom, a carbonyl group, an oxy group or a combination thereof, and still more preferably a group containing a hydroxy group, a sulfo group, a fluorine atom, a bromine atom, an oxy group or a combination thereof.

For example, a hydrocarbon group having 1 to 20 carbon atoms or the like may bond to the aromatic ring in addition to the hetero atom-containing group.

Examples of the hydrocarbon group salt include chain hydrocarbon group having 1 to 20 carbon atoms, an alicyclic hydrocarbon group having 3 to 20 carbon atoms, aromatic hydrocarbon group having 6 to 20 carbon atoms, and the like.

The “hydrocarbon group” as referred to herein involves a chain hydrocarbon group, an alicyclic hydrocarbon group and an aromatic hydrocarbon group. The “hydrocarbon group” may be a saturated hydrocarbon group or an unsaturated hydrocarbon group. The “chain hydrocarbon group” as referred to herein means a hydrocarbon group not having a ring structure but being constituted only from a chain structure, and involves both a linear hydrocarbon group and a branched hydrocarbon group. The “alicyclic hydrocarbon group” as referred to herein means a hydrocarbon group having as a ring structure, not an aromatic ring structure but only an alicyclic structure, and involves both a monocyclic alicyclic hydrocarbon group and a polycyclic alicyclic hydrocarbon group. It is not necessary that the alicyclic hydrocarbon group is constituted from only the alicyclic structure, and a part thereof may also include a chain structure. The “aromatic hydrocarbon group” as referred to herein means a hydrocarbon group that includes an aromatic ring structure as the ring structure. It is not necessary that the aromatic hydrocarbon group is constituted from only the aromatic ring structure, and a part thereof may also include a chain structure and/or an alicyclic structure.

The chain hydrocarbon group is exemplified by a monovalent chain hydrocarbon group, a chain hydrocarbon group having a valency of (q1+1) obtained by removing q1 hydrogen atom(s) from the monovalent chain hydrocarbon group, and the like, wherein q1 is, for example, an integer of 1 to 10.

Examples of the monovalent chain hydrocarbon group include:

alkyl groups such as a methyl group, an ethyl group, a propyl group and a butyl group;

alkenyl groups such as an ethenyl group, a propenyl group, a butenyl group and a pentenyl group;

alkynyl groups such as an ethynyl group, a propynyl group, a butynyl group and a pentynyl group; and the like.

The alicyclic hydrocarbon group is exemplified by a monovalent alicyclic hydrocarbon group, an alicyclic hydrocarbon group having a valency of (q2+1) obtained by removing q2 hydrogen atom(s) from the monovalent alicyclic hydrocarbon group, and the like, wherein q2 is, for example, an integer of 1 to 10.

Examples of the monovalent alicyclic hydrocarbon group include:

cycloalkyl groups such as a cyclopropyl group, a cyclobutyl group, a cyclopentyl group, a cyclohexyl group, a cyclooctyl group and a cyclodecyl group;

cycloalkenyl groups such as a cyclopropenyl group, a cyclobutenyl group, a cyclopentenyl group, a cyclohexenyl group and a cyclooctenyl group;

monovalent bridged cyclic hydrocarbon groups such as a norbornyl group and an adamantyl group; and the like.

The aromatic hydrocarbon group is exemplified by a monovalent aromatic hydrocarbon group, an aromatic hydrocarbon group having a valency of (q3+1) obtained by removing q3 hydrogen atom(s) from the monovalent aromatic hydrocarbon group, and the like, wherein q3 is, for example an integer of 1 to 10.

Examples of the monovalent aromatic hydrocarbon group include:

aryl groups such as a phenyl group, a naphthyl group, an anthracenyl group, a pyrenyl group, a tolyl group and a xylyl group;

aralkyl groups such as a benzyl group and a phenethyl group; and the like.

The compound (A) preferably has a partial structure (hereinafter, may be also referred to as “partial structure (i)”) represented by the following formula (I). In the partial structure (i), X and W each represent the aforementioned hetero atom-containing group; and Ar represents the aromatic ring.

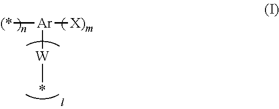

In the above formula (I), Ar represents a group having a valency of (1+n+m) obtained by removing (1+n+m) hydrogen atoms on the aromatic ring from an arene having 6 to 20 carbon atoms; X represents a monovalent hetero atom-containing group; W represents a divalent hetero atom-containing group; * denotes a bonding site to a moiety other than the partial structure represented by the formula (I) in the compound (A); and 1, n and m are each independently, an integer of 0 or 1 or greater, wherein (1+m)≥1, and (1+n)≥1, and in a case in which 1 is 2 or greater, a plurality of Ws may be identical or different; and in a case in which m is 2 or greater, a plurality of Xs may be identical or different.

Examples of the arene having 6 to 20 carbon atoms that gives Ar include: unsubstituted arenes such as benzene, naphthalene, anthracene, pyrene, acenaphthylene, fluorene, phenanthrene, indene and triazine; arenes obtained by substituting one or more hydrogen atoms included in the unsubstituted arene with an alkyl group; and the like.

The alkyl group is exemplified by an alkyl group having 1 to 20 carbon atoms and the like, and is preferably an alkyl group having 1 to 10 carbon atoms, more preferably an alkyl group having 1 to 5 carbon atoms and still more preferably a methyl group.

The number of the alkyl group(s) in the arene substituted with the alkyl group is, for example, no less than 1 and no greater than 10, preferably no less than 1 and no greater than 5, and more preferably no less than 1 and no greater than 3.

The arene having 6 to 20 carbon atoms that gives Ar is preferably benzene, benzene substituted with an alkyl group, naphthalene, naphthalene substituted with an alkyl group, pyrene, and pyrene substituted with an alkyl group, and more preferably benzene, xylene, naphthalene and pyrene.

The monovalent hetero atom-containing group represented by X is exemplified by the monovalent hetero atom-containing group (α), the group (γ) that is monovalent, the group (ω) that is monovalent, the group (δ) that is monovalent, the group (ε) that is monovalent, and the like. Of these, a hydroxy group, a sulfo group, a fluorine atom, a bromine atom and an o-, m- or p-vinylbenzyloxy group are preferred.

The divalent hetero atom-containing group represented by W is exemplified by the divalent hetero atom-containing group (β), the group (γ) that is divalent, the group (ω) that is divalent, the group (δ) that is divalent, the group (ε) that is divalent, and the like. Of these, a carbonyl group, an oxy group, or a group including a combination thereof is preferred, and an oxy group is more preferred.

For example, 1 may be an integer of 0 to 10, and an integer of 0 to 5 is preferred and an integer of 0 to 3 is more preferred.

For example, n may be an integer of 0 to 10, and an integer of 1 to 5 is preferred and an integer of 1 to 3 is more preferred.

For example, m may be an integer of 0 to 10, and an integer of 0 to 5 is preferred and an integer of 1 to 3 is more preferred.

The compound (A) is exemplified by a polymer (hereinafter, may be also referred to as “(a1) polymer” or “polymer (a1)”) or an aromatic ring-containing compound having a molecular weight of no less than 300 and no greater than 3,000 that is a compound other than the polymer (hereinafter, may be also referred to as “(a2) aromatic ring-containing compound” or “aromatic ring-containing compound (a2)”), and the like.

(a1) Polymer

The polymer (a1) has an aromatic ring, and a hetero atom-containing group that bonds to the aromatic ring. It is preferred that the polymer (a1) has a structural unit including an aromatic ring and a hetero atom-containing group (hereinafter, may be also referred to as “structural unit (I)”). The polymer (a1) may have one type of the structural unit (I), or two or more types of the structural unit (I).

The structural unit (I) is exemplified by, as described later, a structural unit (I-1) represented by the following formula (I-1), a structural unit (I-2) represented by the following formula (I-2), a structural unit (I-3) represented by the following formula (I-3), and the like. Each structural unit will be described below.

Structural Unit (I-1)

The structural unit (I-1) is represented by the following formula (I-1).

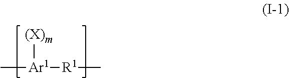

In the above formula (I-1), X and m are as defined in the above formula (I); Ar¹ represents a group having a valency of (m+2) obtained by removing (m+2) hydrogen atoms on the aromatic ring from an arene having 6 to 20 carbon atoms; R¹ represents a single bond, an oxy group, a carbonyl group, a carbonyloxy group, a sulfoxide group, a sulfonyl group, a substituted or unsubstituted alkanediyl group having 1 to 20 carbon atoms, a substituted or unsubstituted arylene group having 6 to 20 carbon atoms, or a substituted or unsubstituted oxyalkanediyl group having 1 to 20 carbon atoms, wherein in a case in which R¹ represents a single bond, an unsubstituted alkanediyl group having 1 to 20 carbon atoms, or an unsubstituted arylene group having 6 to 20 carbon atoms, m≥1.

The arene having 6 to 20 carbon atoms that gives Ar¹ is exemplified by arenes similar to those exemplified as the arene that gives Ar in the above formula (I), and the like. Of these, unsubstituted arenes are preferred, and benzene, xylene, naphthalene and pyrene are more preferred.

Examples of the alkanediyl group which may be represented by R¹ include a methanediyl group, an ethanediyl group, a n-propanediyl group, an i-propanediyl group, a n-butanediyl group, a tert-butanediyl group, and the like.

Examples of the arylene group which may be represented by R¹ include a phenylene group, a methylphenylene group, a phenylenemethylene group, a phenylmethylene group, a phenylethylene group, and the like.

The oxyalkanediyl group which may be represented by R¹ is exemplified by a group that includes an oxy group at the end of the atomic bonding side of the alkanediyl group, and the like.

In a case in which the alkanediyl group, the arylene group or the oxyalkanediyl group represented by R¹ is substituted, the substituent is exemplified by the aforementioned monovalent hetero atom-containing group, and the like. The number of the substituents included in R¹ is exemplified by 0 or greater and 10 or less, preferably 0 or greater and 5 or less, and more preferably 0 or greater and 2 or less.

The number of carbon atoms of the substituted or unsubstituted alkanediyl group, the substituted or unsubstituted arylene group and the substituted or unsubstituted oxyalkanediyl group which may be represented by R¹ is preferably 1 or greater and 10 or less.

R¹ represents preferably a single bond, an oxy group, a substituted or unsubstituted alkylene group having 1 to 20 carbon atoms, or a substituted or unsubstituted arylene group having 6 to 20 carbon atoms, more preferably a single bond, an oxy group, a substituted or unsubstituted methylene group, or a substituted or unsubstituted phenylmethylene group, and still more preferably a single bond, an oxy group, a methylene group or a hydroxyphenylmethylene group.

Structural Unit (I-2)

The structural unit (I-2) is represented by the following formula (I-2).

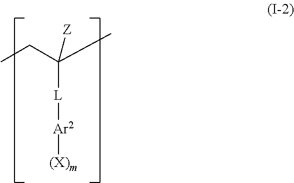

In the above formula (I-2), X and m are as defined in the above formula (I); Ar² represents a group obtained by removing (m+1) hydrogen atoms on the aromatic ring from an arene having 6 to 20 carbon atoms; L represents a single bond, —O—, —COO— or —CONH—; Z represents a hydrogen atom, a fluorine atom, a methyl group or a trifluoromethyl group, wherein in a case in which L represents a single bond, m≥1.

The arene having 6 to 20 carbon atoms that gives Ar² is exemplified by arenes similar to those exemplified as the arene that gives Ar in the above formula (I), and the like. Of these, unsubstituted arenes are preferred, and benzene, xylene, naphthalene and pyrene are more preferred.

L represents preferably a single bond or —COO—.

Z represents preferably a hydrogen atom or a methyl group, in light of polymerizability of a monomer that gives the structural unit (I-2).

Structural Unit (I-3)

The structural unit (I-3) is represented by the following formula (I-3) and has a cardo skeleton.

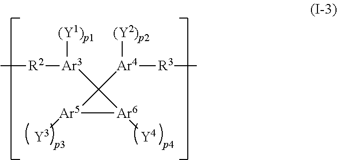

In the above formula (I-3), Y¹ to Y⁴ each independently represent a monovalent hetero atom-containing group; R² and R³ each independently represent a single bond, an oxy group, a carboxy group, a sulfonium group, a substituted or unsubstituted alkanediyl group having 1 to 20 carbon atoms, a substituted or unsubstituted arylene group having 6 to 20 carbon atoms, or a substituted or unsubstituted oxyalkanediyl group having 1 to 20 carbon atoms; Ar³ represents a group having a valency of (p1+2) obtained by removing (p1+2) hydrogen atoms on the aromatic ring from an arene having 6 to 20 carbon atoms; Ar⁴ represents a group having a valency of (p2+2) obtained by removing (p2+2) hydrogen atoms on the aromatic ring from an arene having 6 to 20 carbon atoms; Ar⁵ represents a group having a valency of (p3+2) obtained by removing (p3+2) hydrogen atoms on the aromatic ring from an arene having 6 to 20 carbon atoms; Ar⁶ represents a group having a valency of (p4+2) obtained by removing (p4+2) hydrogen atoms on the aromatic ring from an arene having 6 to 20 carbon atoms; p1 to p4 are each independently an integer of 0 or 1 or greater, wherein in a case in which R² and R³ both represent a single bond, an unsubstituted alkanediyl group having 1 to 20 carbon atoms or an unsubstituted arylene group having 6 to 20 carbon atoms, at least one or more of p1 to p4 is an integer of 1 or greater, wherein, in a case in which p1 is 2 or greater, a plurality of Y¹s may be identical or different; in a case in which p2 is 2 or greater, a plurality of Y²s may be identical or different; in a case in which p3 is 2 or greater, a plurality of Y³s may be identical or different; and in a case in which p4 is 2 or greater, a plurality of Y⁴s may be identical or different.

The alkanediyl group, an arylene group, an oxyalkanediyl group which may be represented by R² or R³, and a substituent for these groups are exemplified by groups similar to those exemplified for R¹ in the above formula (I-1), and the like.

The number of carbon atoms of the substituted or unsubstituted alkanediyl group, the substituted or unsubstituted arylene group, and the substituted or unsubstituted oxyalkanediyl group which may be represented by R² or R³ is preferably 1 or greater and 10 or less.

R² represents preferably a single bond.

R³ represents preferably a substituted or unsubstituted alkanediyl group, more preferably an unsubstituted alkanediyl group, and still more preferably a methanediyl group.

The monovalent hetero atom-containing group represented by Y¹, Y², Y³, or Y⁴ may be similar to the monovalent group represented by X in the above formula (I), and the like, and of these, a hydroxy group is preferred.

The sum of p1 to p4 may be, for example, an integer of 1 to 10, and is preferably an integer of 1 to 5 and more preferably an integer of 1 to 3.

For example, p1 to p4 may be an integer of 0 to 10, and is preferably an integer of 0 to 3.

It is preferred p1 and p2 are 1 or 2.

It is preferred that p3 and p4 are 0.

In the polymer (a1), two or more of the structural units (I-1) to (I-3) may be included in combination, and it is preferred that only one of the structural units (I-1) to (I-3) is included.

In a case in which the polymer (a1) has the structural units (I-1) to (I-3), the lower limit of the proportion of a total of the structural units (I-1) to (I-3) contained with respect to the total structural units constituting the polymer (a1) is preferably 1 mol %, more preferably 20 mol %, still more preferably 50 mol %, and particularly preferably 80 mol %. When the proportion of the total of the structural units (I-1) to (I-3) contained is greater than the lower limit, the substrate-pattern collapse-inhibitory property and the substrate-pattern defect-inhibitory property may be improved.

The polymer (a1) is exemplified by a phenol resin, a naphthol resin, a fluorene resin, a styrene resin, an acenaphthylene resin, an indene resin, an arylene resin, an aromatic polyether resin, a pyrene resin, a calixarene resin, an and the like.

Phenol Resin

The phenol resin is a polymer having a structural unit derived from a phenol compound. Exemplary structural units include the structural unit (I-1) represented by the above formula (I-1), wherein: the arene that gives Ar¹ is benzene unsubstituted or substituted with an alkyl group; and R¹ represents a substituted or unsubstituted alkanediyl group, and the like. The phenol resin which may be used is exemplified by a novolak resin obtained by allowing the phenol compound to react with an aldehyde compound using an acidic catalyst or an alkaline catalyst, as well as a derivative thereof, and the like.

Examples of the phenol compound include phenol, benzenediol, benzenetriol, cresol, xylenol, resorcinol, bisphenol A, p-tert-butylphenol, p-octylphenol, etc., as well as compounds obtained by substituting one or a plurality of hydrogen atoms on the aromatic ring of any of these compounds with a halogen atom, a sulfo group or the like, and the like. Examples of the halogen atom include a bromine atom, a chlorine atom, a fluorine atom, and the like.

Examples of the aldehyde compound include aldehydes such as formaldehyde, aldehyde sources such as paraformaldehyde and trioxane, and the like.

Naphthol Resin

The naphthol resin is a polymer having a structural unit derived from a naphthol compound. Exemplary structural units include the structural unit (I-1) represented by the above formula (I-1), wherein: the arene that gives Ar¹ is naphthalene being unsubstituted or substituted with an alkyl group; and R¹ represents a substituted or unsubstituted alkanediyl group, and the like. The naphthol resin which may be used is exemplified by a polymer obtained by allowing a the naphthol compound to react with the aldehyde compound using an acidic catalyst or an alkaline catalyst, as well as a derivative thereof, and the like.

Examples of the naphthol compound include α-naphthol, β-naphthol, 1,5-dihydroxynaphthalene, 2,7-dihydroxynaphthalene, etc., as well as compounds obtained by substituting one or a plurality of hydrogen atoms on the aromatic ring of any of these compounds with a halogen atom, a sulfo group or the like, and the like. Examples of the halogen atom include a bromine atom, a chlorine atom, a fluorine atom, and the like.

Fluorene Resin

The fluorene resin is a polymer having a structural unit derived from a fluorene compound. Exemplary structural units include the structural unit (I-3) represented by the above formula (I-3), wherein R² represents a single bond, and R³ represents a substituted or unsubstituted alkanediyl group, and the like. The fluorene resin which may be used is exemplified by a polymer obtained by allowing the fluorene compound to react with the aldehyde compound using an acidic catalyst or an alkaline catalyst, as well as a derivative thereof, and the like.

Examples of the fluorene compound include 9,9-bis(4-hydroxyphenyl)fluorene, 9,9-bis(4-hydroxyphenyl)fluorene, 9,9-bis(6-hydroxynaphthyl)fluorene, and the like.

Styrene Resin

The styrene resin is a polymer having a structural unit derived from a compound that includes an aromatic ring and an ethylenic carbon-carbon double bond. Exemplary structural units include the structural unit (I-2) represented by the above formula (I-2), wherein L represents a single bond, and the like. The styrene resin which may be used is exemplified by a polymer obtained by allowing a compound having an ethylenic carbon-carbon double bond and an aromatic ring bonding to a phenolic hydroxy group to react, as well as a derivative thereof, and the like. The “phenolic hydroxy group” as referred to herein means a hydroxy group bonding to an aromatic ring.

Acenaphthylene Resin

The acenaphthylene resin is a polymer having a structural unit derived from an acenaphthylene compound. The acenaphthylene resin which may be used is exemplified by a polymer having a structural unit derived from an acenaphthylene compound that includes a phenolic hydroxy group, as well as a derivative thereof, and the like.

Indene Resin

The indene resin is a polymer having a structural unit derived from an indene compound. The indene resin which may be used is exemplified by a polymer having a structural unit derived from an indene compound that includes a phenolic hydroxy group, as well as a derivative thereof, and the like.

Arylene Resin

The arylene resin is a polymer having a structural unit that includes an arylene skeleton. Exemplary structural units include the structural unit (I-1) represented by the above formula (I-1), wherein R¹ represents a single bond, and the like. The arylene resin which may be used is exemplified by a polymer having an arylene skeleton that includes a phenolic hydroxy group, as well as a derivative thereof, and the like. Examples of the arylene skeleton include a phenylene skeleton, a naphthylene skeleton, a biphenylene skeleton, and the like.

Aromatic Polyether Resin

The aromatic polyether resin is a polymer having a structural unit that includes an aromatic ring and an oxy group bonding to the aromatic ring. Exemplary structural units include the structural unit (I-1) represented by the above formula (I-1), wherein R¹ represents an oxy group, the structural unit (I-3) represented by the above formula (I-3), wherein R² represents a single bond; and R³ represents an oxy group, and the like.

Examples of the aromatic polyether resin include aromatic polyether (polyarylene ether), poly(oxyfluoroarylene), aromatic polyether nitrile, aromatic polyether ketone, aromatic polyether sulfone, and the like. It is to be noted that aromatic polyether ether nitrile, aromatic polyether ether ether nitrile, aromatic polyether ether ketone, aromatic polyether ether ether ketone, aromatic polyether ether sulfone, aromatic polyether ether ether sulfone and the like fall under the concept of the aromatic polyether nitrile, the aromatic polyether ketone and the aromatic polyether sulfone.

The aromatic polyether resin is preferably aromatic polyether and poly(oxyfluoroarylene), and more preferably aromatic polyether and poly(oxytetrafluorophenylene).

Pyrene Resin

The pyrene resin is a polymer having a structural unit that includes a pyrene skeleton. The pyrene resin which may be used is exemplified by a polymer having a pyrene skeleton that includes a phenolic hydroxy group, as well as a derivative thereof, and the like. Exemplary structural units include the structural unit (I-1) represented by the above formula (I-1), wherein the arene that gives Ar¹ is pyrene, and R¹ represents a substituted or unsubstituted alkanediyl group, and the like. The polymer having a pyrene skeleton that includes the phenolic hydroxy group is obtained by allowing, for example, a pyrene compound having a phenolic hydroxy group to react with the aldehyde compound using an acidic catalyst.

In the case in which the polymer (a1) is the phenol resin, the naphthol resin, the fluorene resin, the styrene resin, the acenaphthylene resin, the indene resin, the arylene resin, the aromatic polyether resin or the pyrene resin, the lower limit of the Mw of the polymer (a1) is preferably 500, and more preferably 1,000. Meanwhile, the upper limit of the Mw is preferably 50,000, more preferably 20,000, still more preferably 12,000, and particularly preferably 3,500. When the Mw of the polymer (a1) falls within the above range, the coating characteristics of the treatment agent may be more improved. The “weight average molecular weight” may be determined in terms of a polystyrene equivalent value by gel permeation chromatography (GPC), for example.

Calixarene Resin

The calixarene resin is a cyclic oligomer in which a plurality of aromatic rings bonding to phenolic hydroxy groups bond via hydrocarbon groups to be cyclic. To the calixarene resin, a hetero atom-containing group other than the phenolic hydroxy group may be introduced by using a phenol structure, for example.

In the case in which the polymer (a1) is the calixarene resin, the lower limit of the molecular weight thereof is preferably 500, more preferably 700, and still more preferably 1,000. Meanwhile, the upper limit of the molecular weight is preferably 5,000, more preferably 3,000, and still more preferably 1,500. When the molecular weight falls within the above range, coating characteristics of the treatment agent may be more improved.

(a2) Aromatic Ring-Containing Compound

The aromatic ring-containing compound (a2) is a compound other than the polymer, and is an aromatic ring-containing compound having a molecular weight of no less than 300 and no greater than 3,000. The molecular weight of the aromatic ring-containing compound (a2) is determined as polystyrene equivalent weight average molecular weight (Mw) by gel permeation chromatography (GPC), for example. Examples of the aromatic ring-containing compound (a2) include tannic acid, and the like.

Tannic Acid

The tannic acid as referred to is a generic name of aromatic compounds contained in various types of plant, and having a large number of phenolic hydroxy groups. Tannic acid may be classify broadly into: condensed tannic acid formed by polymerization of a compound having a flavanol skeleton; and hydrolyzable tannic acid formed by ester bonding between an aromatic compound such as gallic acid or ellagic acid and a saccharide such as glucose, and any one may be used in the embodiment of the present invention. The tannic acid is not particularly limited, and examples thereof include hamameli tannin, persimmon tannin, tea tannin, gallnut tannin, gallic tannin, myrobalan tannin, divi-divi tannin, Algarovilla tannin, Valonia tannin, catechin tannin, and the like. A specific example of the hydrolyzable tannic acid is a compound represented by the following formula, and the like. The tannic acid may be either one type of the compound, or a mixture of two or more types of the compound.

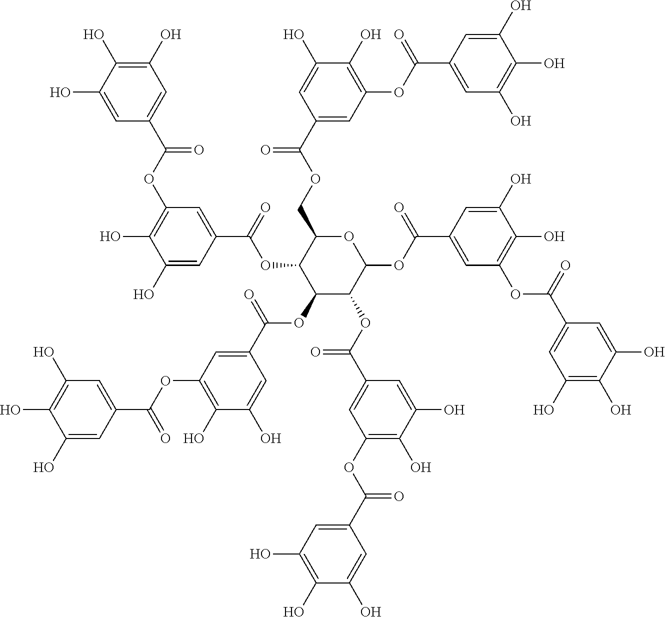 [SMILES: O=C(OC[C@H]1OC(OC(=O)c2cc(O)c(O)c(OC(=O)c3cc(O)c(O)c(O)c3)c2)[C@H](OC(=O)c2cc(O)c(O)c(OC(=O)c3cc(O)c(O)c(O)c3)c2)[C@@H](OC(=O)c2cc(O)c(O)c(OC(=O)c3cc(O)c(O)c(O)c3)c2)[C@@H]1OC(=O)c1cc(O)c(O)c(OC(=O)c2cc(O)c(O)c(O)c2)c1)c1cc(O)c(O)c(OC(=O)c2cc(O)c(O)c(O)c2)c1]

Examples of commercially available products of the tannic acid include “Tannic acid extract A”, “B tannic acid”, “N tannic acid”, “Industrially used tannic acid”, “Purified tannic acid”, “Hi tannic acid”, “F tannic acid” and “Pharmacopoeial tannic acid” (all manufactured by Nihon Pharmaceutical Co., Ltd.), “Tannic acid: AL” (manufactured by Fuji Chemical Industry Co., Ltd.), “G tannic acid”, “F tannic acid” and “Hi tannic acid” (all manufactured by DSP Gokyo Food & Chemical Co., Ltd.), and the like.

The lower limit of the molecular weight of the aromatic ring-containing compound (a2) is preferably 400, more preferably 500, and still more preferably 600. Meanwhile, the upper limit of the molecular weight is preferably 2,500, more preferably 2,000, and still more preferably 1,800. When the molecular weight of the aromatic ring-containing compound (a2) falls within the above range, the coating characteristics of the treatment agent may be more improved.

The compound (A) is preferably the aromatic ring-containing compound having a molecular weight of no less than 300 and no greater than 3,000, the phenol resin, the naphthol resin, the fluorene resin, the styrene resin, the acenaphthylene resin, the indene resin, the arylene resin, the aromatic polyether resin, the pyrene resin, the calixarene resin and a combination thereof, and more preferably the phenol resin, the naphthol resin, the fluorene resin, the styrene resin, the aromatic polyether resin, the pyrene resin and a combination thereof.

The lower limit of the proportion of the hetero atom contained in the compound (A) is preferably 1% by mass, more preferably 3% by mass, and still more preferably 5% by mass. Meanwhile, the upper limit of the content is preferably 90% by mass, more preferably 80% by mass, and still more preferably 70% by mass. When the content in the compound (A) falls within the above range, the coating characteristics and the filling property of the treatment agent may be more improved. In this respect, the “proportion of the hetero atom contained” may be determined by an element analysis or the like.

The lower limit of the content of the compound (A) in the treatment agent is preferably 0.1% by mass, more preferably 5% by mass, and still more preferably 15% by mass. Meanwhile, the upper limit of the content is preferably 50% by mass, more preferably 40% by mass, and still more preferably 30% by mass. When the content of the compound (A) falls within the above range, the coating characteristics and the filling property of the treatment agent may be more improved.

(B) Solvent

The solvent (B) used in the treatment agent is not particularly limited, and for example, a polar solvent such as water or a polar organic solvent may be used. The solvent (B) may be used either alone of one type, or in combination of two or more types thereof.

The polar organic solvent is not particularly limited, and in light of the filling property for the substrate pattern, an alcohol, an ester, an alkyl ether of a polyhydric alcohol, a hydroxyketone, a carboxylic acid, an ether, a ketone, a nitrile, an amide, an amine and the like may be exemplified.

Examples of the alcohol include: monohydric alcohols such as methanol, ethanol, propanol, n-butanol, n-pentanol, n-hexanal and isopropanol; and polyhydric alcohols such as ethylene glycol, propylene glycol, diethylene glycol, dipropylene glycol, triethylene glycol and tripropylene glycol. Of these, methanol and isopropanol are preferred, and isopropanol is particularly preferred.

Examples of the ester include: n-butyl acetate; hydroxycarboxylic acid esters such as ethyl lactate, methyl glycolate, ethyl glycolate, methyl hydroxypropionate, ethyl hydroxypropionate, methyl hydroxybutyrate and ethyl hydroxybutyrate; polyhydric alcohol carboxylates such as propylene glycol acetate; polyhydric alcohol partial ether carboxylates such as propylene glycol monomethyl ether acetate; polyhydric carboxylic acid diesters such as diethyl oxalate; carbonates such as dimethyl carbonate and diethyl carbonate; and the like.

Examples of the alkyl ether of a polyhydric alcohol include: monoalkyl ethers of a polyhydric alcohol such as ethylene glycol monoethyl ether, propylene glycol monomethyl ether, ethylene glycol monopropyl ether, propylene glycol monoproplyl ether, ethylene glycol monobutyl ether and propylene glycol monobutyl ether; polyalkyl ethers of a polyhydric alcohol such as ethylene glycol dimethyl ether, propylene glycol dimethyl ether, ethylene glycol diethyl ether, propylene glycol diethyl ether, ethylene glycol dipropyl ether, propylene glycol dipropyl ether, ethylene glycol dibutyl ether and propylene glycol dibutyl ether; and the like.

Examples of the hydroxyketone include: α-hydroxyketones such as hydroxyacetone, 1-hydroxy-2-butanone, 1-hydroxy-2-pentanone, 3-hydroxy-2-butanone and 4-hydroxy-3-pentanone; β-hydroxyketones such as 4-hydroxy-2-butanone, 3-methyl-4-hydroxy-2-butanone, diacetone alcohol, 4-hydroxy-5,5-dimethyl-2-hexanone; 5-hydroxy-2-pentanone; 5-hydroxy-2-hexanone; and the like.

Examples of the carboxylic acid include formic acid, acetic acid, and the like.

Examples of the ether include tetrahydrofuran, 1,4-dioxane, dimethoxyethane, polyethylene oxide, and the like.

Examples of the ketone include acetone, methyl ethyl ketone, and the like.

Examples of the nitrile include acetonitrile and the like.

Examples of the amide include N,N-dimethylformamide, N,N-dimethylacetamide, and the like.

Examples of the amine include triethylamine, pyridine, and the like.

In light of the coating characteristics and the filling property for the substrate pattern, the solvent (B) is preferably the polar solvent, more preferably the polar organic solvent, still more preferably the ester and the alkyl ether of the polyhydric alcohol, particularly preferably the hydroxycarboxylic acid ester, the polyhydric alcohol partial ether carboxylate and the monoalkyl ether of the polyhydric alcohol, and further particularly preferably ethyl lactate, propylene glycol monomethyl ether acetate, and propylene glycol monoethyl ether.

It is preferred that the polar organic solvent is, in light of the filling property for the substrate pattern, capable of forming a no less than 1% by mass aqueous solution at 20° C.

The lower limit of the dielectric constant of the solvent (B) is, in light of the filling property for the substrate pattern, preferably 6.0. The dielectric constant of the solvent (B) as referred to herein means a value determined by using a dielectric constant meter for liquid.

(C) Acid Generating Agent

The acid generating agent (C) is a component that is capable of generating an acid by an action of heat and/or light to promote the crosslinking of molecules of the compound (A). When the treatment agent contains the acid generating agent (C), the crosslinking reaction of molecules of the compound (A) is promoted and consequently the hardness of the formed film is enabled to be further increased. The acid generating agent (C) may be used either alone of one type, or in combination of two or more types thereof.

The acid generating agent (C) is exemplified by an onium salt compound, an N-sulfonyloxyimide compound, and the like.

The onium salt compound is exemplified by a sulfonium salt, a tetrahydrothiophenium salt, an iodonium salt, an ammonium salt, and the like.

Examples of the sulfonium salt include triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, 4-cyclohexylphenyldiphenylsulfonium trifluoromethanesulfonate, 4-cyclohexylphenyldiphenylsulfonium nonafluoro-n-butanesulfonate, 4-cyclohexylphenyldiphenylsulfonium perfluoro-n-octanesulfonate, 4-cyclohexylphenyldiphenylsulfonium 2-bicyclo[2.2.1]hept-2-yl-1,1,2,2-tetrafluoroethanesulfonate, 4-methanesulfonylphenyldiphenylsulfonium trifluoromethanesulfonate, 4-methanesulfonylphenyldiphenylsulfonium nonafluoro-n-butanesulfonate, 4-methanesulfonylphenyldiphenylsulfonium perfluoro-n-octanesulfonate, 4-methanesulfonylphenyldiphenylsulfonium 2-bicyclo[2.2.1]hept-2-yl-1,1,2,2-tetrafluoroethanesulfonate, and the like.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(6-n-butoxynaphthalen-2-yl)tetrahydrothiophenium trifluoromethanesulfonate, 1-(6-n-butoxynaphthalen-2-yl)tetrahydrothiophenium nonafluoro-n-butanesulfonate, 1-(6-n-butoxynaphthalen-2-yl)tetrahydrothiophenium perfluoro-n-octanesulfonate, 1-(6-n-butoxynaphthalen-2-yl)tetrahydrothiophenium 2-bicyclo[2.2.1]hept-2-yl-1,1,2,2-tetrafluoroethanesulfonate, 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, 1-(3,5-dimethyl-4-hydroxyphenyl)tetrahydrothiophenium perfluoro-n-octanesulfonate, 1-(3,5-dimethyl-4-hydroxyphenyl)tetrahydrothiophenium 2-bicyclo[2.2.1]hept-2-yl-1,1,2,2-tetrafluoroethanesulfonate, and the like.

Examples of the iodonium salt include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-bicyclo[2.2.1]hept-2-yl-1,1,2,2-tetrafluoroethanesulfonate, and the like.

Examples of the ammonium salt include triethylammonium trifluoromethanesulfonate, triethylammonium nonafluoro-n-butanesulfonate, trimethylammonium nonafluoro-n-butanesulfonate, tetraethylammonium nonafluoro-n-butanesulfonate, triethylammonium perfluoro-n-octanesulfonate, triethylammonium 2-bicyclo[2.2.1]hept-2-yl-1,1,2,2-tetrafluoroethanesulfonate, and the like.

Examples of the N-sulfonyloxyimide compound include N-(trifluoromethanesulfonyloxy)bicyclo[2.2.1]hept-5-ene-2,3-dicarboxyimide, N-(nonafluoro-n-butanesulfonyloxy)bicyclo[2.2.1]hept-5-ene-2,3-dicarboxyimide, N-(perfluoro-n-octanesulfonyloxy)bicyclo[2.2.1]hept-5-ene-2,3-dicarboxyimide, N-(2-bicyclo[2.2.1]hept-2-yl-1,1,2,2-tetrafluoroethanesulfonyloxy)bicyclo[2.2.1]hept-5-ene-2,3-dicarboxyimide, and the like.

Of these, the acid generating agent (C) is preferably the onium salt compound, more preferably the iodonium salt and the ammonium salt, and still more preferably diphenyliodonium nonafluoro-n-butanesulfonate, bis(4-t-butylphenyl)iodonium nonafluoro-n-butanesulfonate and triethylammonium nonafluoro-n-butanesulfonate.

In the case in which the treatment agent contains the acid generating agent (C), the lower limit of the content of the acid generating agent (C) with respect to 100 parts by mass of the compound (A) is preferably 0.01 parts by mass, more preferably 0.1 parts by mass, and still more preferably 0.2 parts by mass. Meanwhile, the upper limit of the content with respect to 100 parts by mass of the compound (A) is preferably 20 parts by mass, more preferably 5 parts by mass, and still more preferably 1 part by mass. When the content of the acid generating agent (C) falls within the above range, the substrate-pattern collapse-inhibitory property and the substrate-pattern defect-inhibitory property may be more improved.

Additive

As needed, the treatment agent may further contain an additive being an optional component within the range not leading to impairment of the object of the present invention. The additive may be used either alone of one type, or in combination of two or more types thereof.

The additive is preferably (D) a surfactant. When the treatment agent further contains the surfactant (D), the coating characteristics and the filling property for the substrate pattern may be more improved. The surfactant (D) is exemplified by a nonionic surfactant, a cationic surfactant, an anionic surfactant, and the like.

The nonionic surfactant is exemplified by: ether type nonionic surfactants such as polyoxyethylene alkyl ethers; ether-ester type nonionic surfactants such as polyoxyethylene ethers of a glycerin ester; ester type nonionic surfactants such as polyethylene glycol fatty acid esters, glycerin esters and sorbitan esters, and the like. Examples of the commercially available product of the nonionic surfactant include: “Newcol 2320”, “Newcol 714-F”, “Newcol 723”, “Newcol 2307” and “Newcol 2303” (all manufactured by Nipon Nyukazai Co., Ltd.); “Pionin D-1107-S”, “Pionin D-1007” and “Pionin D-1106-DIR” and “Newkalgen TG310” (all manufactured by TAKEMOTO OIL & FAT Co., Ltd); “DYNAFLOW” (manufactured by JSR Corporation); and the like.

The cationic surfactant salt is exemplified by aliphatic amine salts, aliphatic ammonium salts, and the like.

Examples of the anionic surfactant salt include: carboxylic acid salts such as fatty acid soap and alkyl ether carboxylic acid salts; sulfonic acid salts such as alkylbenzene sulfonic acid salts, alkylnaphthalene sulfonic acid salts and α-olefin sulfonic acid salts; sulfuric acid ester salts such as higher alcohol sulfuric acid ester salts and alkylether sulfuric acid salts; phosphoric acid ester salts such as alkyl phosphate esters; and the like.

The surfactant (D) is, in light of the coating characteristics of the treatment agent and the filling property for the substrate, the nonionic surfactant is preferred.

In the case in which the treatment agent contains the surfactant (D), the lower limit of the content of the surfactant (D) in the treatment agent is preferably 0.0001% by mass, more preferably 0.001% by mass, still more preferably 0.01% by mass, and particularly preferably 0.05% by mass. Meanwhile, the upper limit of the content of the surfactant is preferably 1% by mass, more preferably 0.5% by mass, and still more preferably 0.2% by mass.

Metal Content

It is preferred that the treatment agent does not contain a metal as much as possible in light of reduction in contamination of the substrate pattern. Examples of the metal include sodium, potassium, magnesium, calcium, copper, aluminum, iron, manganese, tin, chromium, nickel, zinc, lead, titanium, zirconium, silver, platinum, and the like. The form of the metal is not particularly limited, and may be for example, a metal cation, a metal complex, a simple metal and an ionic compound, or the like.

The upper limit of the total content of the metal in the treatment agent is preferably 30 ppb by mass, more preferably 20 ppb by mass, and still more preferably 10 ppb by mass. The upper limit of the total content of the metal is not particularly limited, which is preferably as small as possible, and for example, 1 ppb by mass.

It is to be noted that the element and the content of the metal in the treatment agent may be determined by, for example, inductively coupled plasma-mass spectrometry (ICP-MS), or the like.

The contact angle (at 25° C., 50% RH) with water on the surface of the substrate pattern collapse-inhibitory film formed with the treatment agent is preferably less than 90°, and more preferably no greater than 70°. In a case in which the contact angle with water is no less than 90°, the filling property for the substrate pattern may be deteriorated. The substrate pattern collapse-inhibitory film for use in the measurement of the contact angle with water is formed on a silicon substrate under a baking condition at 120° C. for 1 min in the ambient air.

Production Method of Treatment Agent

The treatment agent may be produced by mixing the compound (A) and the solvent (B), as well as optional component(s) which may be blended as needed, and thereafter filtering the solution thus obtained through, for example, a filter having a pore size of about 0.02 μm. The lower limit of the solid content concentration of the treatment agent is preferably 0.1% by mass, more preferably 1% by mass, still more preferably 3% by mass, and particularly preferably 10% by mass. The upper limit of the solid content concentration is preferably 50% by mass, more preferably 40% by mass, and still more preferably 30% by mass. The “solid content” in the treatment agent as referred to herein means component(s) other than the solvent (B).

In addition, it is preferred that the treatment agent thus obtained is further filtered through a nylon filter (for example, a filter employing a nylon 66 film as a filtration medium), an ion exchange filter, or a filter that adopts an adsorptive action by zeta potential. The filtration with a nylon filter, an ion exchange filter, or a filter that adopts an adsorptive action by zeta potential in this manner enables the content of the metal in the treatment agent to be conveniently and reliably reduced, whereby the treatment agent having a comparatively low metal content can be obtained at a low cost. It is to be noted that in the treatment agent, for example, the metal content may be reduced also by purification with a well-known method involving a chemical purification procedure such as washing with water, liquid-liquid extraction, etc., as well as a combination of the chemical purification procedure with a physical purification procedure such as ultrafiltration, centrifugal separation, etc.

### Substrate-Treating Method

The substrate-treating method of the another embodiment of the present invention includes a step of forming a substrate patterns collapse-inhibitory film by applying the treatment agent directly or indirectly on one face of the substrate, the substrate having a pattern on the one face (substrate pattern collapse-inhibitory film-forming step). The substrate-treating method is superior in substrate-pattern collapse-inhibitory property and substrate-pattern defect-inhibitory property due to the treatment agent used.

The substrate to be treated in the substrate-treating method is not particularly limited as long as a substrate pattern is formed on at least one face, and is preferably a substrate including a silicon atom or a metal atom and more preferably a substrate including a metal, a metal nitride, a metal oxide, silicon oxide, silicon or a mixture of the same as a principal component. The “principal component” as referred to herein means a component included at a maximum content, and for example, a component included at a content of no less than 50% by mass.

A material that constitutes the substrate pattern is exemplified by the materials similar to those exemplified as the substrate described above, and the like.

The configuration of the substrate pattern is not particularly limited, and is exemplified by a line-and-space pattern, a hole pattern, a pillar pattern, and the like. The upper limit of the average interval in the line-and-space pattern is preferably 300 nm, more preferably 150 nm, still more preferably 100 nm, and particularly preferably 50 nm. The average interval in the hole pattern and the pillar pattern is preferably 300 nm, more preferably 150 nm, and still more preferably 100 nm. By adopting the substrate-treating method of this embodiment to a substrate having a pattern formed with such a minute interval, the superior substrate-pattern collapse-inhibitory property and substrate-pattern defect-inhibitory property can be provided to the full extent.

The lower limit of the average height in the substrate pattern is preferably 100 nm, more preferably 200 nm, and still more preferably 300 nm. The upper limit of the average width of the substrate pattern (for example, reference position being each central portion in the altitude direction) is preferably 50 nm, more preferably 40 nm, and still more preferably 30 nm. The lower limit of the aspect ratio of the substrate pattern (i.e., pattern average height/pattern average width) is preferably 3, more preferably 5, and still more preferably 10. By adopting the substrate-treating method of this embodiment to a substrate having such a fine pattern formed with such a high aspect ratio, the superior substrate-pattern collapse-inhibitory property and substrate-pattern defect-inhibitory property can be provided to the full extent.

Substrate Pattern Collapse-Inhibitory Film-Forming Step

In this step, the treatment agent of the one embodiment of the present invention is applied directly or indirectly on one face of a substrate to form a substrate pattern collapse-inhibitory film, the substrate having a pattern on the one face. Accordingly, even if liquids such as a washing liquid and a rinse agent are retained on the substrate, removal of these liquids is enabled without drying. Following this step and until the removing step described later, at least a part of the substrate pattern is filled with the substrate pattern collapse-inhibitory film, and thus each pattern wall is supported by the substrate pattern collapse-inhibitory film, thereby enabling pattern collapse such as contact of adjacent pattern walls to be inhibited.

On the substrate, liquids such as the washing liquid and the rinse agent are typically retained. Therefore, in this step, the treatment agent is applied while the washing liquid or the rinse agent is replaced with the treatment agent.

The applying procedure of the treatment agent is not particularly limited, and for example, an appropriate procedure such as spin-coating, cast coating and roll coating may be employed. After the applying, the treatment agent may be dried as needed.

The procedure of the drying is not particularly limited, and may involve, for example, a heating procedure in an ambient air atmosphere. In this case, the lower limit of the heating temperature is not particularly limited, and is preferably 40° C., more preferably 50° C., and still more preferably 60° C. Meanwhile, the upper limit of the heating temperature is preferably 200° C., and more preferably 150° C. The lower limit of the heating time period is preferably 15 sec, more preferably 30 sec, and still more preferably 45 sec. The upper limit of the heating time period is preferably 1,200 sec, more preferably 600 sec, and still more preferably 300 sec.

In this step, the average thickness of the substrate pattern collapse-inhibitory film to be formed may be greater than the maximum height of the substrate pattern walls such that the substrate pattern is completely filled with the substrate pattern collapse-inhibitory film. When the substrate pattern is thus filled completely with the substrate pattern collapse-inhibitory film, substrate pattern collapse can be more readily inhibited. In this case, the lower limit of the difference between the average thickness of the substrate pattern collapse-inhibitory film and the maximum height of the substrate pattern walls (i.e., a result of subtraction: (average thickness of the substrate pattern collapse-inhibitory film)−(maximum height of the substrate pattern walls)) is preferably 0.01 μm, more preferably 0.02 μm, and still more preferably 0.05 μm. The upper limit of the difference is preferably 5 μm, more preferably 3 μm, still more preferably 2 μm, and particularly preferably 0.5 μm.

In contrast, the average thickness of the substrate pattern collapse-inhibitory film to be formed may be equal to or less than the maximum height of the substrate pattern walls in this step such that the a part of the substrate pattern is exposed from the substrate pattern collapse-inhibitory film. Also in this case, the substrate pattern at around the bottom is filled with the substrate pattern collapse-inhibitory film and therefore, the substrate pattern collapse can be sufficiently inhibited.

Removing Step

The substrate-treating method further includes typically, a step of removing the substrate pattern collapse-inhibitory film (removing step) after the substrate pattern collapse-inhibitory film-forming step. In removing the substrate pattern collapse-inhibitory film, for example, a heat treatment, a plasma treatment, dry etching (ashing), ultraviolet ray-irradiation, electron beam-irradiation or the like may be employed. These procedures enable the substrate pattern collapse-inhibitory film to be converted directly from the solid phase to the gaseous phase, whereby inhibition of the pattern collapse resulting from passage of a gas-liquid interface along lateral faces in the substrate pattern is enabled.

The dry etching may be conducted by using a well-known dry etching apparatus. An etching gas used in the dry etching may be appropriately selected in accordance with elemental composition, etc., of the substrate pattern collapse-inhibitory film to be etched, and examples of the etching gas which may be used include: fluorine-based gasses such as CHF₃, CF₄, C₂F₆, C₃F₈ and SF₆; chlorine-based gasses such as Cl₂ and BCl₃; oxygen-based gasses such as O₂, O₃ and H₂O; reductive gasses such as H₂, NH₃, CO, CO₂, CH₄, C₂H₂, C₂H₄, C₂H₆, C₃H₄, C₃H₆, C₃H₈, HF, HI, HBr, HCl, NO, NH₃ and BCl₃; inert gasses such as He, N₂ and Ar; and the like. It is to be noted that the these gasses may be used as a mixture.

The lower limit of the substrate temperature in the dry etching is not particularly limited, and preferably −120° C., more preferably −50° C., still more preferably 20° C., particularly preferably 80° C., and most preferably 180° C. Meanwhile, the upper limit of the substrate temperature is preferably 800° C., more preferably 400° C., still more preferably 300° C., and particularly preferably 270° C.

In a substrate-washing method including: a step of washing a substrate (washing step); and a step of treating the substrate after washing (treatment step), the substrate-treating method of the another embodiment of the present invention may be suitably used for the treatment step. This washing method may be suitably used for washing of a substrate after wet etching or after dry etching.

In the washing step, at least one of washing of the substrate with a washing liquid and rinsing of the substrate with a rinse agent is carried out. The washing liquid is exemplified by a sulfuric acid ion-containing washing liquid, a chlorine ion-containing washing liquid, a fluorine ion-containing washing liquid, a nitrogen compound-containing alkaline washing liquid, a phosphoric acid-containing washing liquid, and the like. In the washing of the substrate, washing with two or more types of washing liquids may be continuously carried out. It is preferred that the washing liquid contains hydrogen peroxide. The sulfuric acid ion-containing washing liquid is preferably a liquid prepared by mixing hydrogen peroxide and sulfuric acid, i.e., a sulfuric acid peroxide mixture (SPM), which enables the organic matter such as resist to be suitably removed. The chlorine ion-containing washing liquid is preferably a mixed aqueous solution of hydrogen peroxide and hydrochloric acid (SC-2), which enables the metal to be suitably removed. Examples of the fluorine ion-containing washing liquid include mixed aqueous solutions of hydrofluoric acid and ammonium fluoride. The nitrogen compound-containing alkaline washing liquid is preferably a mixed aqueous solution of hydrogen peroxide and ammonia (SC-1), which enables particles to be suitably removed. The rinse agent is exemplified by ultra pure water, and the like.

### EXAMPLES

Hereinafter, the embodiments of the present invention will be described in more detail by way of Examples, but the present invention is not in any way limited to these Examples.

Mw and Mn

The weight average molecular weight (Mw) and the number average molecular weight (Mn) of each polymer of Examples were determined by using: a gel permeation chromatograph (“HLC-8220” available from Tosoh Corporation) equipped with GPC columns (“G2000HXL”×1, “G3000HXL”×1, and“G4000HHR”) available from Tosoh Corporation; and a polystyrene standard sample (“Easical PS-1” available from Agilent Technologies Japan, Ltd.), under analytical conditions involving a flow rate of 1.00 mL/min, an elution solvent of tetrahydrofuran, and a column temperature of 40° C.

### Synthesis of Compound (A)

### Synthesis Example 1: Synthesis of Compound (A-1)

Into a 1,000-mL three-neck flask equipped with a thermometer, a condenser and a magnetic stirrer were charged 500 g of phenol, 106 g of 86% paraformaldehyde and 13 g of 37% formaldehyde in a nitrogen atmosphere, and 1.46 g of zinc acetate was added thereto. The reaction was then allowed with reflux for 4 hrs. Next, after the reaction mixture was left to stand to separate into the organic layer and the aqueous layer, the upper aqueous layer was removed. Thereafter, the remaining underlayer, i.e., the organic layer, was subjected to reduced pressure of 2 mmHg at 150° C. to so as to remove the moisture and unreacted monomer molecules, whereby a compound (A-1) that is a phenol resin having a structural unit represented by the following formula (A-1) was obtained. Thus obtained compound (A-1) had the Mw of 1,500.

### Synthesis Example 2: Synthesis of Compound (A-2)

Into a 1,000-mL three-neck flask equipped with a thermometer, a condenser and a magnetic stirrer were charged 150 g of phenol, 129.36 g of 37% formaldehyde and 450 g of methyl isobutyl ketone in a nitrogen atmosphere, and dissolution was allowed at room temperature. To the solution thus obtained was added 2.74 g of paratoluenesulfonic acid at a solution temperature of 40° C., and thereafter the solution temperature was elevated to 80° C., followed by aging for 7 hrs. After the aging, the flask was cooled until the solution temperature reached room temperature. The reaction mixture was added to 5,000 g of methanol, and thus precipitated solid matter was collected by removing the methanol solution through filtration. Subsequently, washing of the collected solid matter with a flowing mixed solution of methanol and water (each 300 g) was carried out, followed by drying under reduced pressure at 60° C. overnight, whereby a compound (A-2) that is a phenol resin having a structural unit represented by the following formula (A-2) was obtained. Thus obtained compound (A-2) had the Mw of 10,000.

### Synthesis Example 3: Synthesis of Compound (A-3)

Into a 1,000-mL three-neck flask equipped with a thermometer, a condenser and a magnetic stirrer were charged 150 g of 2,7-dihydroxynaphthalene, 76.01 g of 37% formaldehyde and 450 g of methyl isobutyl ketone in a nitrogen atmosphere, and dissolution was allowed at room temperature. To the solution thus obtained was added 1.61 g of paratoluenesulfonic acid at a solution temperature of 40° C., and thereafter the solution temperature was elevated to 80° C., followed by aging for 7 hrs. After the aging, the flask was cooled until the solution temperature reached room temperature. The reaction mixture was added to a mixed solution of methanol and water (each 2,500 g), and thus precipitated solid matter was collected by removing the mixed solution of methanol and water through filtration. Subsequently, washing of the collected solid matter with a flowing mixed solution of methanol and water (each 300 g) was carried out, followed by drying under reduced pressure at 60° C. overnight, whereby a compound (A-3) that is a naphthol resin having a structural unit represented by the following formula (A-3) was obtained. Thus obtained compound (A-3) had the Mw of 3,000.

### Synthesis Example 4: Synthesis of Compound (A-4)

Into a 1,000-mL three-neck flask equipped with a thermometer, a condenser and a magnetic stirrer were charged 150 g of pyrogallol, 96.54 g of 37% formaldehyde and 450 g of methyl isobutyl ketone in a nitrogen atmosphere, and dissolution was allowed at room temperature. To the solution thus obtained was added 2.05 g of paratoluenesulfonic acid at a solution temperature of 40° C., and thereafter the solution temperature was elevated to 80° C., followed by aging for 7 hrs. After the aging, the flask was cooled until the solution temperature reached room temperature. The reaction mixture was added to 5,000 g of hexane, and thus precipitated solid matter was collected by removing hexane through filtration. Subsequently, washing of the collected solid matter with 600 g of flowing hexane was carried out, followed by drying under reduced pressure at 60° C. overnight, whereby a compound (A-4) that is a phenol resin having a structural unit represented by the following formula (A-4) was obtained. Thus obtained compound (A-4) had the Mw of 10,000.

### Synthesis Example 5: Synthesis of Compound (A-5)

Into a 1,000-mL three-neck flask equipped with a thermometer, a condenser and a magnetic stirrer were charged 150 g of paraphenolsulfonic acid, 69.90 g of 37% formaldehyde and 450 g of methanol in a nitrogen atmosphere, and dissolution was allowed at room temperature. To the solution thus obtained was added 1.48 g of paratoluenesulfonic acid at a solution temperature of 40° C., and thereafter the solution temperature was elevated to 60° C., followed by aging for 7 hrs. After the aging, the flask was cooled until the solution temperature reached room temperature, whereby a compound (A-5) that is a phenol resin having a structural unit represented by the following formula (A-5) was obtained. Thus obtained compound (A-5) had the Mw of 10,000.

### Synthesis Example 6: Synthesis of Compound (A-6)

Into a 1,000-mL three-neck flask equipped with a thermometer, a condenser and a magnetic stirrer were charged 150 g of 2-naphthol-6-sulfonic acid, 54.29 g of 37% formaldehyde and 450 g of methanol in a nitrogen atmosphere, and dissolution was allowed at room temperature. To the solution thus obtained was added 1.15 g of paratoluenesulfonic acid at a solution temperature of 40° C., and thereafter the solution temperature was elevated to 60° C., followed by aging for 7 hrs. After the aging, the flask was cooled until the solution temperature reached room temperature, whereby a compound (A-6) that is a naphthol resin having a structural unit represented by the following formula (A-6) was obtained. Thus obtained compound (A-6) had the Mw of 2,500.

### Synthesis Example 7: Synthesis of Compound (A-7)

Into a 1,000-mL three-neck flask equipped with a thermometer, a condenser and a magnetic stirrer were charged 150 g of phenol, 194.64 g of 4-hydroxybenzaldehyde and 450 g of methyl isobutyl ketone in a nitrogen atmosphere, and dissolution was allowed at room temperature. To the solution thus obtained was added 2.74 g of paratoluenesulfonic acid at a solution temperature of 40° C., and thereafter the solution temperature was elevated to 80° C., followed by aging for 7 hrs. After the aging, the flask was cooled until the solution temperature reached room temperature. The reaction mixture was added to a mixed solution of methanol and water (each 2,500 g), and thus precipitated solid matter was collected by removing the mixed solution of methanol and water through filtration. Subsequently, washing of the collected solid matter with a flowing mixed solution of methanol and water (each 300 g) was carried out, followed by drying under reduced pressure at 60° C. overnight, whereby a compound (A-7) that is a phenol resin having a structural unit represented by the following formula (A-7) was obtained. Thus obtained compound (A-7) had the Mw of 10,000.

### Synthesis Example 8: Synthesis of Compound (A-8)

Into a 1,000-mL three-neck flask equipped with a thermometer, a condenser and a magnetic stirrer were charged 150 g of paraphenolsulfonic acid, 105.17 g of 4-hydroxybenzaldehyde and 450 g of methanol in a nitrogen atmosphere, and dissolution was allowed at room temperature. To the solution thus obtained was added 1.48 g of paratoluenesulfonic acid at a solution temperature of 40° C., and thereafter the solution temperature was elevated to 60° C., followed by aging for 7 hrs. After the aging, the flask was cooled until the solution temperature reached room temperature, whereby a compound (A-8) that is a phenol resin having a structural unit represented by the following formula (A-8) was obtained. Thus obtained compound (A-8) had the Mw of 10,000.

### Synthesis Example 9: Synthesis of Compound (A-9)

Into a 1,000-mL three-neck flask equipped with a thermometer, a condenser and a magnetic stirrer were charged 150 g of 1-hydroxypyrene, 55.78 g of 37% formaldehyde and 450 g of methyl isobutyl ketone in a nitrogen atmosphere, and dissolution was allowed at room temperature. To the solution thus obtained was added 1.18 g of paratoluenesulfonic acid at a solution temperature of 40° C., and thereafter the solution temperature was elevated to 80° C., followed by aging for 7 hrs. After the aging, the flask was cooled until the solution temperature reached room temperature. The reaction mixture was added to a mixed solution of methanol and water (each 2,500 g), and thus precipitated solid matter was collected by removing the mixed solution of methanol and water through filtration. Subsequently, washing of the collected solid matter with a flowing mixed solution of methanol and water (each 300 g) was carried out, followed by drying under reduced pressure at 60° C. overnight, whereby a compound (A-9) that is a pyrene resin having a structural unit represented by the following formula (A-9) was obtained. Thus obtained compound (A-9) had the Mw of 3,000.

### Synthesis Example 10: Synthesis of Compound (A-10)

Into a 1,000-mL three-neck flask equipped with a thermometer, a condenser and a magnetic stirrer were charged 150 g of 4,4′-(9H-fluoren-9-ylidene)bisphenol, 34.74 g of 37% formaldehyde and 450 g of methyl isobutyl ketone in a nitrogen atmosphere, and dissolution was allowed at room temperature. To the solution thus obtained was added 0.74 g of paratoluenesulfonic acid at a solution temperature of 40° C., and thereafter the solution temperature was elevated to 80° C., followed by aging for 7 hrs. After the aging, the flask was cooled until the solution temperature reached room temperature. The reaction mixture was added to a mixed solution of methanol and water (each 2,500 g), and thus precipitated solid matter was collected by removing the mixed solution of methanol and water through filtration. Subsequently, washing of the collected solid matter with a flowing mixed solution of methanol and water (each 300 g) was carried out, followed by drying under reduced pressure at 60° C. overnight, whereby a compound (A-10) that is a fluorene resin having a structural unit represented by the following formula (A-10) was obtained. Thus obtained compound (A-10) had the Mw of 10,000.

### Synthesis Example 11: Synthesis of Compound (A-11)

Into a 1,000-mL three-neck flask equipped with a thermometer, a condenser and a magnetic stirrer were charged 150 g of 3,5-difluorophenol, 93.58 g of 37% formaldehyde and 450 g of methyl isobutyl ketone in a nitrogen atmosphere, and dissolution was allowed at room temperature. To the solution thus obtained was added 1.99 g of paratoluenesulfonic acid at a solution temperature of 40° C., and thereafter the solution temperature was elevated to 80° C., followed by aging for 7 hrs. After the aging, the flask was cooled until the solution temperature reached room temperature. The reaction mixture was added to a mixed solution of methanol and water (each 2,500 g), and thus precipitated solid matter was collected by removing the mixed solution of methanol and water through filtration. Subsequently, washing of the collected solid matter with a flowing mixed solution of methanol and water (each 300 g) was carried out, followed by drying under reduced pressure at 60° C. overnight, whereby a compound (A-11) that is a phenol resin having a structural unit represented by the following formula (A-11) was obtained. Thus obtained compound (A-11) had the Mw of 10,000.

### Synthesis Example 12: Synthesis of Compound (A-12)

Into a 1,000-mL three-neck flask equipped with a thermometer, a condenser and a magnetic stirrer were charged 150 g of 3,5-dibromophenol, 48.33 g of 37% formaldehyde and 450 g of methyl isobutyl ketone in a nitrogen atmosphere, and dissolution was allowed at room temperature. To the solution thus obtained was added 1.03 g of paratoluenesulfonic acid at a solution temperature of 40° C., and thereafter the solution temperature was elevated to 80° C., followed by aging for 7 hrs. After the aging, the flask was cooled until the solution temperature reached room temperature. The reaction mixture was added to a mixed solution of methanol and water (each 2,500 g), and thus precipitated solid matter was collected by removing the mixed solution of methanol and water through filtration. Subsequently, washing of the collected solid matter with a flowing mixed solution of methanol and water (each 300 g) was carried out, followed by drying under reduced pressure at 60° C. overnight, whereby a compound (A-12) that is a phenol resin having a structural unit represented by the following formula (A-12) was obtained. Thus obtained compound (A-12) had the Mw of 10,000.

### Synthesis Example 13: Synthesis of Compound (A-13)

Into a 1,000-mL three-neck flask equipped with a thermometer, a condenser and a magnetic stirrer were charged 80 g of 1,4-dihydroxybenzene, 69.08 g of 1,4-difluorobenzene, 100.41 g of potassium carbonate as an alkali metal compound, 450 g of dimethylacetamide and 90 g of toluene in a nitrogen atmosphere. The resulting mixture was subjected to aging with stirring at a solution temperature of 140° C. for 8 hrs. After the aging, the flask was cooled until the solution temperature reached room temperature. The reaction mixture after filtration was added to 5,000 g of methanol, and thus precipitated solid matter was collected by removing methanol through filtration. Subsequently, washing of the collected solid matter with a flowing mixed solution of methanol and water (each 300 g) was carried out, followed by drying under reduced pressure at 60° C. overnight, whereby a compound (A-13) that is a polyarylene ether having a structural unit represented by the following formula (A-13) was obtained. Thus obtained compound (A-13) had the Mw of 10,000.

### Synthesis Example 14: Synthesis of Compound (A-14)

Into a 1,000-mL three-neck flask equipped with a thermometer, a condenser and a magnetic stirrer were charged 80 g of 1,2,4,5-tetrafluoro-3,6-dihydroxybenzene, 68.13 g of hexafluorobenzene, 60.72 g of potassium carbonate as an alkali metal compound, 450 g of dimethylacetamide and 90 g of toluene in a nitrogen atmosphere. The mixture was subjected to aging with stirring at a solution temperature of 140° C. for 8 hrs. After the aging, the flask was cooled until the solution temperature reached room temperature. The reaction mixture after filtration was added to 5,000 g of methanol, and thus precipitated solid matter was collected by removing methanol through filtration. Subsequently, washing with a mixed solution of methanol and water (each 300 g) was carried out, followed by drying under reduced pressure at 60° C. overnight, whereby a compound (A-14), a polymer, that is a polyarylene ether having a structural unit represented by the following formula (A-14) was obtained. Thus obtained compound (A-14) had the Mw of 10,000.

### Synthesis Example 15: Synthesis of Compound (a-1)

Into a 1,000-mL three-neck flask equipped with a thermometer, a condenser and a magnetic stirrer were charged 270 g of styrene, 21.29 g of azobisisobutyronitrile and 630 g of propylene glycol monomethyl ether in a nitrogen atmosphere, and dissolution was allowed at room temperature. Next, the solution temperature was elevated to 70° C. to permit polymerization for 10 hrs. Following the polymerization, the flask was cooled until the solution temperature reached room temperature. Ethyl acetate was added to the obtained polymer, and washing with water was repeated five times. Then an ethyl acetate layer was collected, and the solvent was removed, whereby a compound (a-1) that is a polystyrene having a structural unit represented by the following formula (a-1) was obtained. Thus obtained compound (a-1) had the Mw of 10,000.

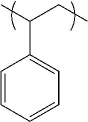

### Synthesis Example 16: Synthesis of Compound (A-17)

Into a reaction vessel were charged 15.0 g of resorcinol, 6 g of acetaldehyde and 105 g of ethanol in a nitrogen atmosphere, and dissolution was allowed at room temperature. To the solution thus obtained was added 40.1 g of concentrated hydrochloric acid over 1 hour dropwise. Thereafter the solution temperature was elevated to 80° C., followed by aging for 7 hrs. After the aging, the solution was cooled until the solution temperature reached room temperature. Thereafter, reddish brown solid matter precipitated was collected by removing the ethanol solution through filtration, whereby solid matter that serves as a precursor was obtained. Next, into a reaction vessel were charged 15.0 g of the precursor obtained, 30.0 g of 4-methyl-2-pentanone, 15.0 g of methanol and 81.7 g of a 25% by mass aqueous tetramethylammonium hydroxide solution in a nitrogen atmosphere, and dissolution was allowed at room temperature. Thereafter, the temperature was elevated to 50° C., and 34.2 g of 2-chloromethylstyrene was added to the solution dropwise over 30 min, followed by aging at 80° C. for 6 hrs, whereby the resin (A-17) was obtained. Thus obtained compound (A-17) had the Mw of 1,300.

### Synthesis Example 17: Synthesis of Compound (A-18)

Into a 1,000-mL three-neck flask equipped with a thermometer, a condenser and a magnetic stirrer were charged 135 g of styrene, 228 g of p-t-butoxystyrene, 21.29 g of azobisisobutyronitrile and 846 g of propylene glycol monomethyl ether in a nitrogen atmosphere, and dissolution was allowed at room temperature. Next, the solution temperature was elevated to 70° C. to permit polymerization for 10 hrs. Following the polymerization, the flask was cooled until the solution temperature reached room temperature. Sulfuric acid was added to the reaction mixture and the reaction was allowed at 90° C. for 10 hrs. Ethyl acetate was added to the obtained polymer, and washing with water was repeated five times. Then an ethyl acetate layer was collected, and the solvent was removed, whereby a compound (A-18) that is a vinyl resin having a structural unit represented by the following formula (A-18) was obtained. Thus obtained compound (A-18) had the Mw of 10,000.

### Synthesis Example 18: Synthesis of Compound (A-19)

Into a 1,000-mL three-neck flask equipped with a thermometer, a condenser and a magnetic stirrer were charged 160 g of 2-vinylnaphthalene, 274 g of p-t-butoxystyrene, 21.29 g of azobisisobutyronitrile and 1,011 g of propylene glycol monomethyl ether in a nitrogen atmosphere, and dissolution was allowed at room temperature. Next, the solution temperature was elevated to 70° C. to permit polymerization for 10 hrs. Following the polymerization, the flask was cooled until the solution temperature reached room temperature. Sulfuric acid was added to the reaction mixture and the reaction was allowed at 90° C. for 10 hrs. Ethyl acetate was added to the obtained polymer, and washing with water was repeated five times. Then an ethyl acetate layer was collected, and the solvent was removed, whereby a compound (A-19) that is a vinyl resin having a structural unit represented by the following formula (A-19) was obtained. Thus obtained compound (A-19) had the Mw of 10,000.

### Synthesis Example 19: Synthesis of Compound (A-20)

Into a 1,000-mL three-neck flask equipped with a thermometer, a condenser and a magnetic stirrer were charged 160 g of 2-vinylnaphthalene, 228 g of p-t-butoxystyrene, 33 g of butyl acrylate, 21.29 g of azobisisobutyronitrile and 980 g of propylene glycol monomethyl ether in a nitrogen atmosphere, and dissolution was allowed at room temperature. Next, the solution temperature was elevated to 70° C. to permit polymerization for 10 hrs. Following the polymerization, the flask was cooled until the solution temperature reached room temperature. Sulfuric acid was added to the reaction mixture and the reaction was allowed at 90° C. for 10 hrs. Ethyl acetate was added to the obtained polymer, and washing with water was repeated five times. Then an ethyl acetate layer was collected, and the solvent was removed, whereby a compound (A-20) that is a vinyl resin having a structural unit represented by the following formula (A-20) was obtained. Thus obtained compound (A-20) had the Mw of 8,000.

### Synthesis Example 20: Synthesis of Compound (A-21)

Into a 1,000-mL three-neck flask equipped with a thermometer, a condenser and a magnetic stirrer were charged 160 g of 2-vinylnaphthalene, 174 g of vinylbenzyl alcohol, 33 g of butyl acrylate, 21.29 g of azobisisobutyronitrile and 855 g of propylene glycol monomethyl ether in a nitrogen atmosphere, and dissolution was allowed at room temperature. Next, the solution temperature was elevated to 70° C. to permit polymerization for 10 hrs. Following the polymerization, the flask was cooled until the solution temperature reached room temperature. Ethyl acetate was added to the obtained polymer, and washing with water was repeated five times. Then an ethyl acetate layer was collected, and the solvent was removed, whereby a compound (A-21) that is a vinyl resin having a structural unit represented by the following formula (A-21) was obtained. Thus obtained compound (A-21) had the Mw of 6,000.

### Preparation of Treatment Agent

Each component used for preparing the treatment agent is as shown in the following.

(A) Compound

Each compound (A) is shown below. It is to be noted that the proportion of the hetero atom contained in each compound (A) was calculated according to the structural formula.

A-1: phenol resin (A-1) (Mw: 1,500, proportion of the hetero atom contained: 15.1% by mass)

A-2: phenol resin (A-2) (Mw: 10,000, proportion of the hetero atom contained: 15.1% by mass)

A-3: naphthol resin (A-3) (Mw: 3,000, proportion of the hetero atom contained: 18.6% by mass)

A-4: phenol resin (A-4) (Mw: 10,000, proportion of the hetero atom contained: 34.8% by mass)

A-5: phenol resin (A-5) (Mw: 10,000, proportion of the hetero atom contained: 51.6% by mass)

A-6: naphthol resin (A-6) (Mw: 2,500, proportion of the hetero atom contained: 33.9% by mass) A-7: phenol resin (A-7) (Mw: 10,000, proportion of the hetero atom contained: 16.1% by mass)

A-8: phenol resin (A-8) (Mw: 10,000, proportion of the hetero atom contained: 40.3% by mass)

A-9: pyrene resin (A-9) (Mw: 3,000, proportion of the hetero atom contained: 6.1% by mass)

A-10: fluorene resin (A-10) (Mw: 10,000, proportion of the hetero atom contained: 8.1% by mass)

A-11: phenol resin (A-11) (Mw: 10,000, proportion of the hetero atom contained: 38% by mass)

A-12: phenol resin (A-12) (Mw: 10,000, proportion of the hetero atom contained: 66.6% by mass)

A-13: polyarylene ether (A-13) (Mw: 10,000, proportion of the hetero atom contained: 17.4% by mass)

A-14: polyarylene ether (A-14) (Mw: 10,000, proportion of the hetero atom contained: 56.1% by mass)

A-15: parahydroxystyrene resin (A-15) (Mw: 10,000, proportion of the hetero atom contained: 13.3% by mass) (manufactured by Aldrich)

A-16: a compound represented by the following formula (A-16) (tannic acid) (Mw: 1,701.2, proportion of the hetero atom contained: 43.3% by mass)

A-17: calixarene resin (A-17) (Mw: 1,300, proportion of the hetero atom contained: 10.3% by mass)

A-18: styrene resin (A-18) (Mw: 10,000, proportion of the hetero atom contained: 7.1% by mass)

A-19: styrene resin (A-19) (Mw: 10,000, proportion of the hetero atom contained: 7.2% by mass)

A-20: styrene resin (A-20) (Mw: 8,000, proportion of the hetero atom contained: 8.3% by mass)

A-21: styrene resin (A-21) (Mw: 6,000, proportion of the hetero atom contained: 7.9% by mass)

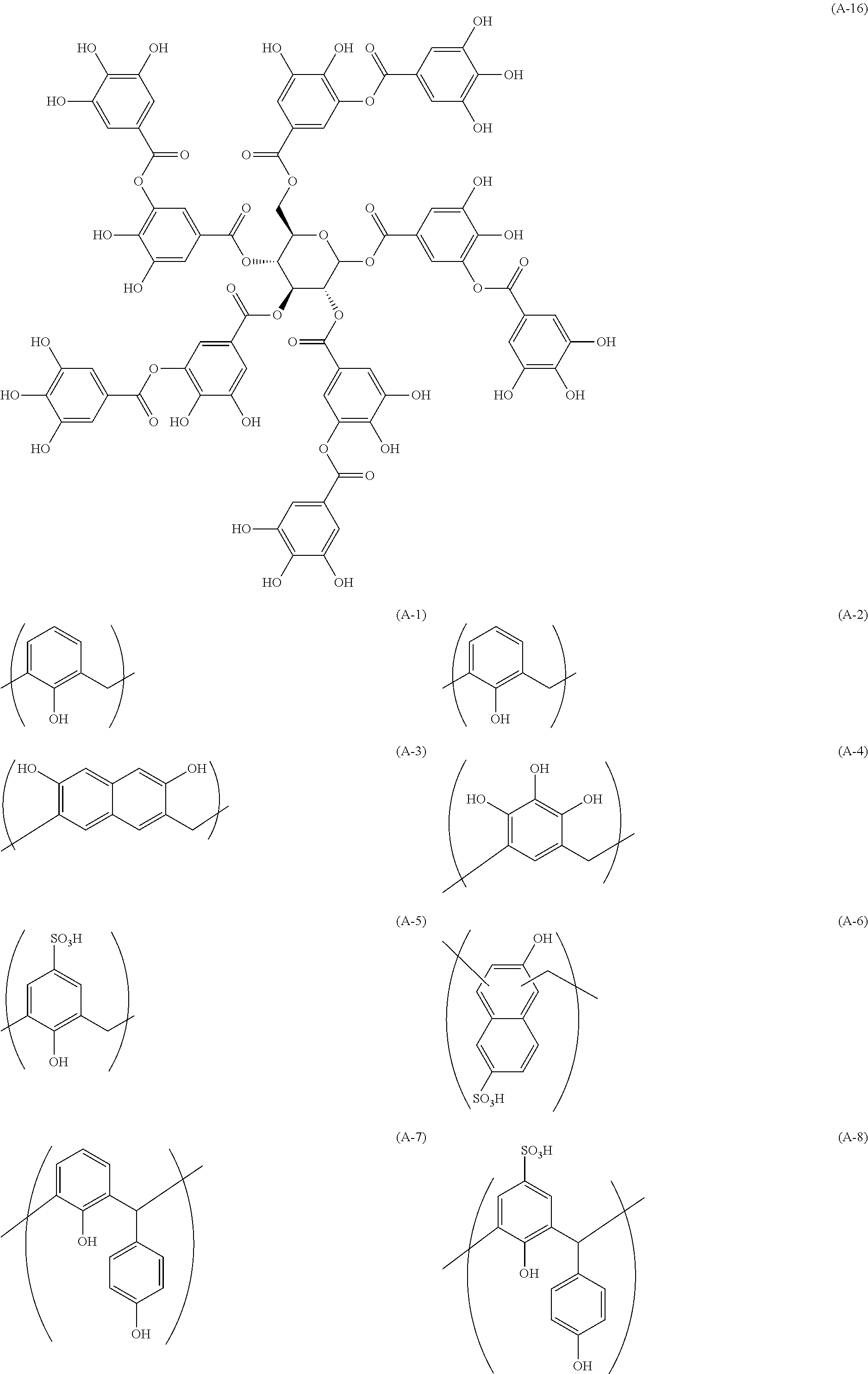

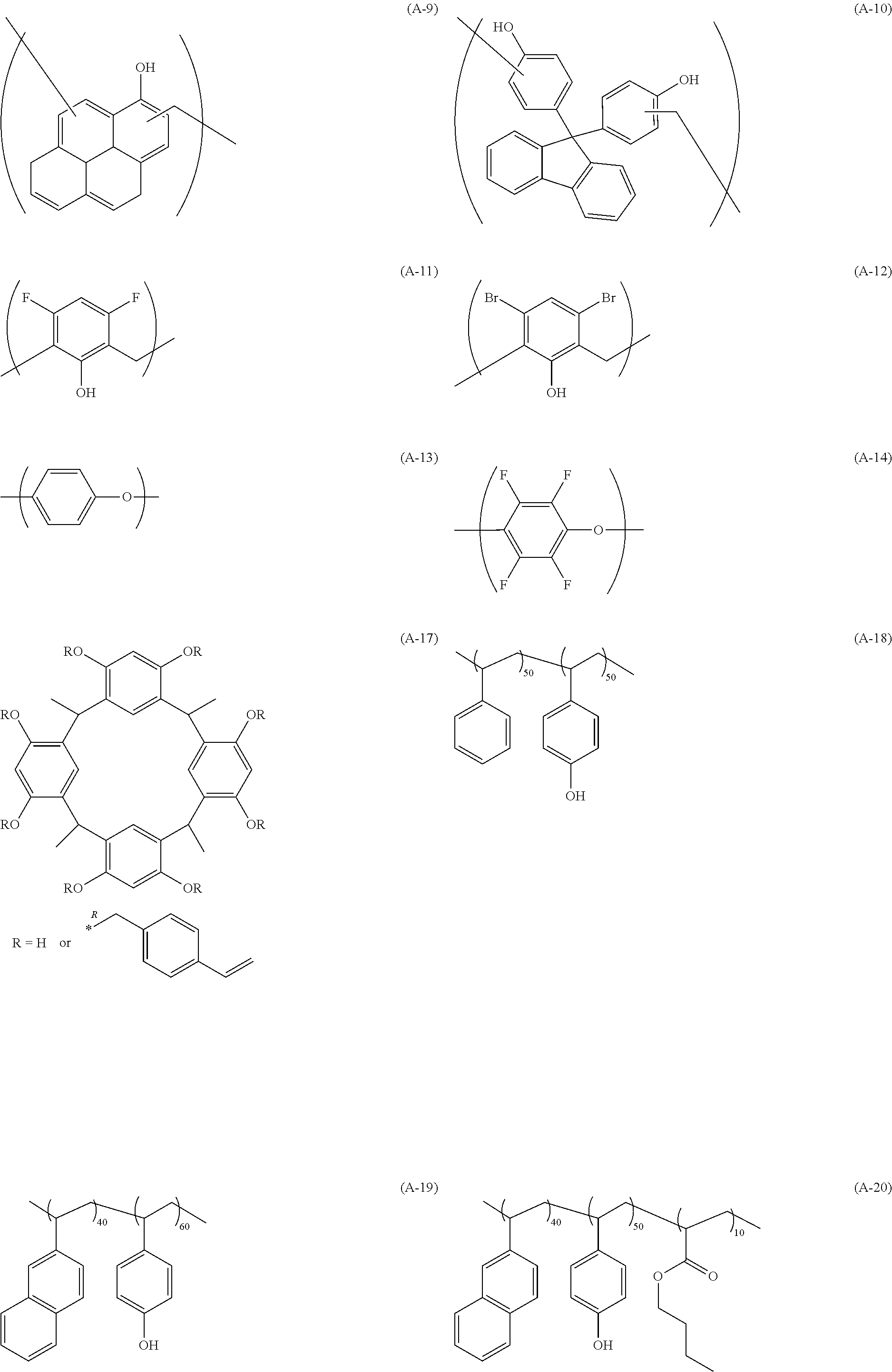

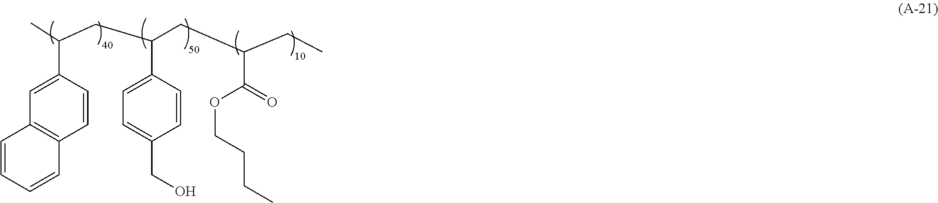

In Comparative Examples 3 and 4, the following polymers were used in place of the compound (A). It is to be noted that the proportion of the hetero atom contained in the following polymer was calculated according to the structural formula.

a-1: polystyrene (Mw: 10,000, proportion of the hetero atom contained: 0% by mass)

a-2: polyvinyl alcohol (degree of polymerization: 500, proportion of the hetero atom contained: 36.3% by mass) (manufactured by Wako Pure Chemical Industries, Ltd.)

(B) Solvent

B-1: water

B-2: isopropanol (IPA)

B-3: propylene glycol monomethyl ether acetate

B-4: propylene glycol monomethyl ether

B-5: methyl lactate

(C) Acid Generating Agent

C-1: diphenyliodonium nonafluoro-n-butanesulfonate represented by the following formula (C-1).

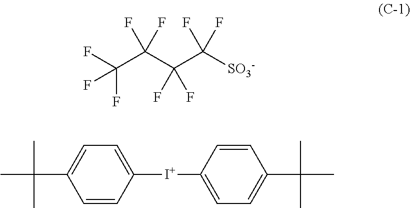

(D) Surfactant

D-1: nonionic surfactant (JSR Corporation, “DYNAFLOW”)

### Example 1

(A-1) in an amount of 25 parts by mass as the compound (A) was dissolved in 100 parts by mass of (B-3) as the solvent (B). The solution thus obtained was filtered through a membrane filter having a pore size of 0.1 μm to prepare a treatment agent of Example 1.

### Examples 2 to 25 and Comparative Examples 1 to 4

Each treatment agent was prepared by a similar operation to that of Example 1 except that the type and the content of each component were as shown in Table 1. It is to be noted that the in Table 1, “-” indicates that the corresponding component was not used.

### Treatment of Substrate

Formation of Substrate Pattern Collapse-Inhibitory Film

Each treatment agent prepared in Examples 1 to 25 and Comparative Examples 1 to 4 was applied by using a simplified spin coater (“1H-DX2” available from Mikasa Co., Ltd.), on one face of a substrate, the substrate having a pattern formed on the one face. The applying was carried out under a condition involving a rotation speed of 500 rpm in an ambient air. The substrate used was a silicon wafer provided with a dense pillar pattern. The pillar pattern included pillars with: the average height of 380 nm; the average width of the upper face (top part) of 35 nm; the average width of the cross section at the central portion in the altitude direction of 20 nm; and the average pitch between the pillars of 100 nm (reference position: the central portion in the width direction of each pillar). Thereafter, the silicon wafer after the applying was baked on a hot plate at 120° C. for 60 sec, whereby the substrate provided with a substrate pattern collapse-inhibitory film was obtained.

### Evaluations

Each treatment agent of Examples 1 to 25 and Comparative Examples 1 to 4 was evaluated on the coating characteristics, the filling property, and the substrate-pattern collapse-inhibitory property as well as the substrate-pattern defect-inhibitory property as in the following. The results of the evaluations are shown in Table 1.

Coating Characteristics

Each silicon wafer substrate on which the substrate pattern collapse-inhibitory film was formed was visually inspected to determine the presence or absence of streaky defects (striations) extending from the center to the circumference. The coating characteristic was determined to be: “A” (extremely favorable) in a case where no streaky defects (striations) were found; “B” (favorable) in a case where defects were found in part of the substrate; and “C” (unfavorable) in a case where defects were found on the entire face of the substrate. The coating characteristic was not evaluated for Comparative Examples 1 to 2 since the substrate pattern collapse-inhibitory film was not formed.

Filling Property

Each silicon wafer substrate on which the substrate pattern collapse-inhibitory film was formed was cut away to be seen in cross section, and each substrate pattern collapse-inhibitory film was evaluated on the filling property in the pattern by using FE-SEM (“S4800” available from Hitachi High-Technologies Corporation). The filling property was determined to be: “A” (extremely favorable) in a case where filling with the substrate pattern collapse-inhibitory film to the bottom part of the pattern was found, without an exposure of the top part of the pattern; “B” (favorable) in a case where the filling with the substrate pattern collapse-inhibitory film to the bottom part of the pattern was found but voids and the like were also found; and “C” (unfavorable) in a case where a failure of filling with substrate pattern collapse-inhibitory film to the bottom of the pattern was found, with the exposure of the top part. The filling property was not evaluated for Comparative Examples 1 to 2 since the substrate pattern collapse-inhibitory film was not formed.

Substrate-Pattern Collapse-Inhibitory Property

Each silicon wafer substrate on which the substrate pattern collapse-inhibitory film was formed was subjected to a dry etching (ashing) treatment by using an ashing apparatus (“Luminous NA-1300” available from ULVAC Technologies, Inc.) with a gas mixture N₂/H₂ (=97/3 (% by volume)), whereby the substrate pattern collapse-inhibitory film was removed. The substrate temperature in the dry etching was 250° C. The number of the pillar remaining on each substrate without collapse after the removal was determined on an observed image obtained by using the FE-SEM. The substrate-pattern collapse-inhibitory property pattern was evaluated to be: “A” (extremely favorable) in a case where more than 90% pillars remained without collapse; “B” (favorable) in a case where more than 70% and 90% or less pillars remained without collapse; and “C” (unfavorable) in a case where 70% or less pillars remained without collapse.

Substrate-Pattern Defect-Inhibitory Property

The substrate after removing the substrate pattern collapse-inhibitory film was observed on FE-SEM described above, and the presence or absence of the residue attached to upper faces (top parts) of the pillars in the field (2,500 nm×2,500 nm) of an observed image was determined. The substrate-pattern defect-inhibitory property was evaluated to be: “A” (favorable) in a case where any residue was not left; and “B” (unfavorable) in a case where the residue remained at one or more positions.

TABLE 1

| | (A) Compound | | (B) Solvent | | (C) Heat acid generating agent | | (D) Surfactant | | | | | |
|---|---|---|---|---|---|---|---|---|---|---|---|---|
| | | content | | content | | content | | content | | | Collapse- | Defect- |
| | | (parts | | (parts | | (parts | | (parts | Coating | Filling | inhibitory | inhibitory |
| | type | by mass) | type | by mass) | type | by mass) | type | by mass) | characteristics | property | property | property |
| Example 1 | A-1 | 25 | B-3 | 100 | — | — | — | — | A | A | A | A |
| Example 2 | A-1 | 25 | B-3/B-4 | 50/50 | — | — | — | — | A | A | A | A |
| Example 3 | A-1 | 25 | B-5 | 100 | — | — | — | — | A | A | A | A |
| Example 4 | A-1 | 25 | B-3 | 100 | C-1 | 0.1 | — | — | A | A | A | A |
| Example 5 | A-2 | 25 | B-3 | 100 | — | — | — | — | B | B | A | A |
| Example 6 | A-2 | 25 | B-3 | 100 | — | — | D-1 | 0.1 | A | A | A | A |
| Example 7 | A-3 | 25 | B-3 | 100 | — | — | — | — | A | A | A | A |
| Example 8 | A-4 | 25 | B-3 | 100 | — | — | — | — | B | B | A | A |
| Example 9 | A-5 | 25 | B-3 | 100 | — | — | — | — | B | B | A | A |
| Example 10 | A-6 | 25 | B-3 | 100 | — | — | — | — | A | A | A | A |
| Example 11 | A-7 | 25 | B-3 | 100 | — | — | — | — | B | B | A | A |
| Example 12 | A-8 | 25 | B-3 | 100 | — | — | — | — | B | B | A | A |
| Example 13 | A-9 | 25 | B-3 | 100 | — | — | — | — | A | A | A | A |
| Example 14 | A-10 | 25 | B-3 | 100 | — | — | — | — | B | B | A | A |
| Example 15 | A-11 | 25 | B-3 | 100 | — | — | — | — | B | B | A | A |
| Example 16 | A-12 | 25 | B-3 | 100 | — | — | — | — | B | B | A | A |
| Example 17 | A-13 | 25 | B-3 | 100 | — | — | — | — | B | B | A | A |
| Example 18 | A-14 | 25 | B-3 | 100 | — | — | — | — | B | B | A | A |
| Example 19 | A-15 | 25 | B-3 | 100 | — | — | — | — | B | B | A | A |
| Example 20 | A-16 | 25 | B-3 | 100 | — | — | — | — | A | A | A | A |
| Example 21 | A-17 | 25 | B-3 | 100 | — | — | — | — | A | A | A | A |
| Example 22 | A-18 | 25 | B-3 | 100 | — | — | — | — | A | B | | A |
| Example 23 | A-19 | 25 | B-3 | 100 | — | — | — | — | A | B | A | A |
| Example 24 | A-20 | 25 | B-3 | 100 | — | — | — | — | A | B | A | A |
| Example 25 | A-21 | 25 | B-3 | 100 | — | — | — | — | A | B | A | A |
| Comparative | — | — | B-1 | 100 | — | — | — | — | — | — | C | — |
| Example 1 | | | | | | | | | | | | |
| Comparative | — | — | B-2 | 100 | — | — | — | — | — | — | C | — |
| Example 2 | | | | | | | | | | | | |
| Comparative | a-1 | 25 | B-3 | 100 | — | — | — | — | A | B | B | B |
| Example 3 | | | | | | | | | | | | |
| Comparative | a-2 | 25 | B-1 | 100 | — | — | — | — | A | B | B | B |
| Example 4 | | | | | | | | | | | | |

As is seen from the results shown in Table 1, the treatment agents of Examples exhibited the coating characteristics, the filling property, as well as the substrate-pattern collapse-inhibitory property and the substrate-pattern defect-inhibitory property, each being favorable or extremely favorable.

The semiconductor substrate treatment agent and the substrate-treating method of the embodiments of the present invention result in a superior substrate-pattern collapse-inhibitory property. In addition, the semiconductor substrate treatment agent and the substrate-treating method of the embodiments of the present invention exhibit superior substrate-pattern defect-inhibitory property in the treatment. Therefore, these can be suitably used in manufacture of semiconductor devices in which further progress of miniaturization is expected in the future.

Obviously, numerous modifications and variations of the present invention are possible in light of the above teachings. It is therefore to be understood that within the scope of the appended claims, the invention may be practiced otherwise than as specifically described herein.

What is claimed is:

1. A substrate-treating method comprising:
applying a treatment agent directly or indirectly on one face of a substrate to form a substrate pattern collapse-inhibitory film, the substrate comprising a pattern on the one face; and
after forming the substrate pattern collapse-inhibitory film, removing the substrate pattern collapse-inhibitory film by dry etching,
the treatment agent comprising:
a compound comprising an aromatic ring, and a hetero atom-containing group that bonds to the aromatic ring; and
a solvent.

2. The substrate-treating method according to claim 1, wherein the substrate comprises a silicon atom or a metal atom.

3. The substrate-treating method according to claim 1, wherein the hetero atom-containing group comprises a hydroxy group, a carboxy group, a cyano group, an amino group, a sulfo group, a carbonyl group, an oxy group, a halogen atom or a combination thereof.

4. The substrate-treating method according to claim 1, wherein the compound is an aromatic ring-containing compound having a molecular weight of no less than 300 and no greater than 3,000, a phenol resin, a naphthol resin, a fluorene resin, a styrene resin, an acenaphthylene resin, an indene resin, an arylene resin, an aromatic polyether resin, a pyrene resin, a calixarene resin or a combination thereof.

5. The substrate-treating method according to claim 1, wherein the solvent is a polar solvent.

6. The substrate-treating method according to claim 5, wherein the polar solvent is an ester, an alkyl ether of a polyhydric alcohol, or a combination thereof.

7. The substrate-treating method according to claim 1, wherein a content of the compound in the treatment agent is no less than 0.1% by mass and no greater than 50% by mass.

8. The substrate-treating method according to claim 1, wherein the treatment agent further comprises a surfactant.

9. A semiconductor substrate treatment agent comprising:
a compound comprising an aromatic ring, and a hetero atom-containing group that bonds to the aromatic ring; and
a solvent,
wherein the semiconductor substrate treatment agent is suitable for forming a film to prevent a collapse of a pattern of a substrate.

10. The semiconductor substrate treatment agent according to claim 9, wherein the hetero atom-containing group comprises a hydroxy group, a carboxy group, a cyano group, an amino group, a sulfo group, a carbonyl group, an oxy group, a halogen atom or a combination thereof.

11. The semiconductor substrate treatment agent according to claim 9, wherein the compound is an aromatic ring-containing compound having a molecular weight of no less than 300 and no greater than 3,000, a phenol resin, a naphthol resin, a fluorene resin, a styrene resin, an acenaphthylene resin, an indene resin, an arylene resin, an aromatic polyether resin, a pyrene resin, a calixarene resin or a combination thereof.

12. The semiconductor substrate treatment agent according to claim 9, wherein the solvent is a polar solvent.

13. The semiconductor substrate treatment agent according to claim 12, wherein the polar solvent is an ester, an alkyl ether of a polyhydric alcohol, or a combination thereof.

14. The semiconductor substrate treatment agent according to claim 9, wherein a content of the compound in the semiconductor substrate treatment agent is no less than 0.1% by mass and no greater than 50% by mass.

15. The semiconductor substrate treatment agent according to claim 9, further comprising a surfactant.
